(19) United States
(12) Patent Application Publication
(10) Pub. No.: US 2026/0255633 A1
(43) Pub. Date: Aug. 27, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Yoshiyuki KUROKAWA, Sagamihara, Kanagawa (JP); Yuto YAKUBO, Atsugi, Kanagawa (JP); Kazuma FURUTANI, Atsugi, Kanagawa (JP); Kouhei TOYOTAKA, Isehara, Kanagawa (JP)

(21) Appl. No.: 18/993,026

(22) PCT Filed: Jun. 30, 2023
(86) PCT No.: PCT/IB2023/056808

§ 371 Date: Jan. 10, 2025

(30) Foreign Application Priority Data
Jul. 15, 2022 (JP) 2022-113611
Oct. 25, 2022 (JP) 2022-170834

(51) Int. Cl. H10D 30/67; G06N 3/08; G11C 11/4096; H10B 12/00; H10D 62/83; H10W 20/41

(52) U.S. Cl. CPC H10D 30/6734; G11C 11/4096; H10B 12/31; H10B 12/50; H10D 30/6755; H10D 62/83; H10W 20/435; G06N 3/08; H10B 12/30

(57) ABSTRACT

A semiconductor device with a novel structure is provided. The semiconductor device includes a first arithmetic device including a register, a second arithmetic device including memory circuits, layer selection circuits, and an arithmetic circuit. The first arithmetic device and the second arithmetic device are each provided in an element layer where a plurality of second element layers are stacked over a first element layer. The register includes flip-flop and data retention circuits. The flip-flop and the arithmetic circuit are provided in the first element layer. The data retention circuits are provided in the plurality of second element layers over the first element layer provided with the flip-flop. The memory circuits and the layer selection circuit are provided in the plurality of second element layers over the first element layer provided with the arithmetic circuit.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include a semiconductor device, a display device, a light-emitting device, a power storage device, a storage device (memory device), a driving method thereof, and a manufacturing method thereof.

### BACKGROUND ART

The technical development of a semiconductor device that can retain electric charges corresponding to data by using a transistor including an oxide semiconductor in its channel formation region (OS transistor) and a transistor including silicon in its channel formation region (Si transistor) in combination has been progressing.

The semiconductor device can achieve low power consumption owing to power gating or the like by having a structure of performing saving (storing or backing up) or loading (restoring or recovering) of a program or data retained in a flip-flop or the like. Thus, the application to a semiconductor device including a CPU (Central Processing Unit) and the like is progressing (see Patent Document 1, for example).

In the CPU, a series of processes (task) is executed by sequentially executing a process corresponding to a program or data.

Data necessary in a process in the CPU or data obtained by the process is transmitted and received between a peripheral circuit and the CPU. A variety of peripheral circuits are used in accordance with the user's needs. Examples of the peripheral circuit include a DRAM (Dynamic Random Access Memory) interface, a PCI (Peripheral Component Interface), a DMA (Direct Memory Access), a network interface, and an audio interface.

In the case where a plurality of tasks are executed, each of the tasks is divided into small processing units and the processing units of each task are sequentially executed, so that it looks as if the plurality of tasks are executed at the same time. In order to execute the processes, a plurality of register banks (sets of general registers) are prepared and switching between the register banks is performed in accordance with the task so that the tasks are executed.

Also in the case where a shift of a program from a main routine to a subroutine is performed, a process of the subroutine is executed after the register bank is switched and a process of the main routine is executed after the process of the subroutine is finished and the register bank is switched to the original register bank.

### REFERENCE

### Patent Document

[Patent Document 1]

Japanese Published Patent Application No. 2013-9297

### SUMMARY OF THE INVENTION

### Problems to be Solved by the Invention

In an arithmetic device such as the CPU conducting a complicated process, when a register bank lacks, data in a register corresponding to the task is temporarily written to an external memory device, and in the case where the task is executed again, the data needs to be written back from the external memory device to the register. In this case, energy is consumed for writing and writing back of data between the external memory device and the register. Preparing a large number of register banks can inhibit energy consumption between the external memory device and the register but leads to an increase in circuit layout area.

In an arithmetic device that performs arithmetic processing that imitates a neural network, arithmetic operation using a data set of weight data is performed. In the case where weight data is stored in an external memory device, the frequency of accessing the external memory device increases by switching the data set to use different weight data in arithmetic processing, whereby energy is consumed for writing and writing back data between the external memory device and an arithmetic circuit. In addition, in the case of accessing the external memory device, it is difficult to switch the weight data in a short time.

One object of one embodiment of the present invention is to provide a novel semiconductor device or the like. Another object of one embodiment of the present invention is to provide a semiconductor device or the like with a novel structure that is excellent in reducing power consumption. Another object of one embodiment of the present invention is to provide a semiconductor device or the like with a novel structure that is excellent in computing performance.

Note that the objects of one embodiment of the present invention are not limited to the objects listed above. The objects listed above do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the above objects and the other objects.

### Means for Solving the Problems

One embodiment of the present invention is a semiconductor device including a first arithmetic device including a register, a second arithmetic device including memory circuits, layer selection circuits, and an arithmetic circuit. The first arithmetic device and the second arithmetic device are each provided in an element layer where a plurality of second element layers are stacked over a first element layer. The first element layer is provided with a first transistor including silicon in a semiconductor layer including a channel formation region. The second element layer is provided with a second transistor including an oxide semiconductor in a semiconductor layer including a channel formation region. The register includes a flip-flop and data retention circuits. The flip-flop and the arithmetic circuit are provided in the first element layer. The data retention circuits are provided in the plurality of second element layers over the flip-flop in the first element layer. The memory circuits and the layer selection circuits are provided in the plurality of second element layers over the arithmetic circuit provided in the first element layer.

In the semiconductor device of one embodiment of the present invention, it is preferable that an input terminal of the flip-flop be electrically connected to output terminals of the data retention circuits, an output terminal of the flip-flop be electrically connected to input terminals of the data retention circuits, and the data retention circuits have a function of retaining data corresponding to a task executed by the first arithmetic device when the second transistor is turned off.

In the semiconductor device of one embodiment of the present invention, it is preferable that the memory circuit include a memory cell electrically connected to a write word line and a read word line, and the layer selection circuit have a function of outputting a signal supplied to the write word line and the read word line.

In the semiconductor device of one embodiment of the present invention, it is preferable that the memory circuits provided in different second element layers each include weight data used for arithmetic processing based on a neural network, and the weight data input to the arithmetic circuit be switched by the layer selection circuit.

In the semiconductor device of one embodiment of the present invention, the data retention circuit preferably includes a region overlapping with the flip-flop in a plan view.

In the semiconductor device of one embodiment of the present invention, the memory circuit preferably includes a region overlapping with the arithmetic circuit in a plan view.

In the semiconductor device of one embodiment of the present invention, the oxide semiconductor preferably includes In, Ga, and Zn.

In the semiconductor device of one embodiment of the present invention, the arithmetic circuit preferably has a function of performing a product-sum operation.

Note that other embodiments of the present invention will be described in the following embodiments with reference to the drawings.

### Effect of the Invention

One embodiment of the present invention can provide a novel semiconductor device or the like. With one embodiment of the present invention, a semiconductor device or the like with a novel structure that is excellent in reducing power consumption can be provided. Another object of one embodiment of the present invention is to provide a semiconductor device or the like with a novel structure that is excellent in computing performance.

Note that the description of these effects does not preclude the existence of other effects. Note that one embodiment of the present invention does not necessarily need to have all these effects. Other effects will be apparent from the descriptions of the specification, the drawings, the claims, and the like, and other effects can be derived from the descriptions of the specification, the drawings, the claims, and the like.

### BRIEF DESCRIPTION OF THE DRAWINGS

FIG. 1A to FIG. 1C are diagrams each illustrating a structure example of a semiconductor device.

FIG. 2A and FIG. 2B are diagrams each illustrating a structure example of a semiconductor device.

FIG. 3A and FIG. 3B are diagrams each illustrating a structure example of a semiconductor device.

FIG. 4A to FIG. 4E are diagrams each illustrating a structure example of a semiconductor device.

FIG. 5 is a diagram illustrating a structure example of a semiconductor device.

FIG. 6A and FIG. 6B are diagrams each illustrating a structure example of a semiconductor device.

FIG. 7A and FIG. 7B are diagrams each illustrating a structure example of a semiconductor device.

FIG. 8A to FIG. 8C are diagrams each illustrating a structure example of a semiconductor device.

FIG. 9 is a diagram illustrating a structure example of a semiconductor device.

FIG. 10A to FIG. 10C are diagrams each illustrating a structure example of a semiconductor device.

FIG. 11 is a diagram illustrating a structure example of a semiconductor device.

FIG. 12 is a diagram illustrating a structure example of a semiconductor device.

FIG. 13A to FIG. 13C are diagrams each showing a structure example of a semiconductor device.

FIG. 14 is a diagram illustrating a structure example of a semiconductor device.

FIG. 15 is a diagram illustrating a structure example of a memory device.

FIG. 16A is a diagram illustrating a structure example of a memory device. FIG. 16B is a diagram illustrating an equivalent circuit of the memory device.

FIG. 17 is a diagram illustrating a structure example of a memory device.

FIG. 18A is a diagram illustrating a structure example of a memory device. FIG. 18B is a diagram illustrating an equivalent circuit of the memory device.

FIG. 19A and FIG. 19B are diagrams each illustrating an example of an electronic component.

FIG. 20A and FIG. 20B are diagrams each illustrating an example of an electronic device, and FIG. 20C to FIG. 20E are diagrams each illustrating an example of a large computer.

FIG. 21 is a diagram illustrating an example of a device for space.

FIG. 22 illustrates an example of a storage system applicable to a data center.

FIG. 23 is a diagram illustrating a structure of an example.

FIG. 24 is a diagram illustrating a structure of an example.

FIG. 25 is a diagram illustrating a structure of an example.

FIG. 26 is a diagram illustrating a structure of an example.

FIG. 27 is a diagram illustrating a structure of an example.

FIG. 28 is a diagram illustrating a structure of an example.

FIG. 29 is a diagram illustrating a structure of an example.

FIG. 30 is a diagram illustrating a structure of an example.

FIG. 31 is a diagram illustrating a structure of an example.

FIG. 32 is a diagram illustrating a structure of an example.

FIG. 33A and FIG. 33B are diagrams each illustrating a structure of an example.

FIG. 34 is a diagram illustrating a structure of an example.

FIG. 35 is a diagram illustrating a structure of an example.

FIG. 36A and FIG. 36B are diagrams each illustrating a structure of an example.

FIG. 37A to FIG. 37C are diagrams each illustrating a structure of an example.

FIG. 38A to FIG. 38C are diagrams each illustrating a structure of an example.

FIG. 39 is a diagram illustrating a structure of an example.

FIG. 40 is a diagram illustrating a structure of an example.

### MODE FOR CARRYING OUT THE INVENTION

Embodiments will be described below with reference to the drawings. Note that the embodiments can be implemented with various modes, and it will be readily appreciated by those skilled in the art that modes and details can be changed in various ways without departing from the spirit and scope of the present invention. Therefore, the present invention should not be construed as being limited to the description of embodiments below.

In the drawings, the size, the layer thickness, or the region is sometimes exaggerated for clarity. Therefore, the size, the layer thickness, or the region is not limited to the illustrated scale. Note that the drawings schematically show ideal examples, and the embodiment of the present invention is not limited to shapes or values shown in the drawings.

Unless otherwise specified, an off-state current in this specification and the like refers to a drain current of a transistor in an off state (also referred to as a non-conduction state or a cutoff state). Unless otherwise specified, an off state refers to, in an n-channel transistor, a state where a voltage V_{gs} between its gate and source is lower than a threshold voltage Vth (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as OS), and the like. For example, a metal oxide used in an active layer of a transistor is referred to as an oxide semiconductor in some cases. That is, an OS transistor can also be referred to as a transistor including a metal oxide or an oxide semiconductor.

### Embodiment 1

In this embodiment, a structure example of a semiconductor device is described.

### Structure example of semiconductor device 10

The semiconductor device described in one embodiment of the present invention has a function of an SoC (System on Chip) in which a plurality of arithmetic devices, memory devices, and the like are tightly coupled.

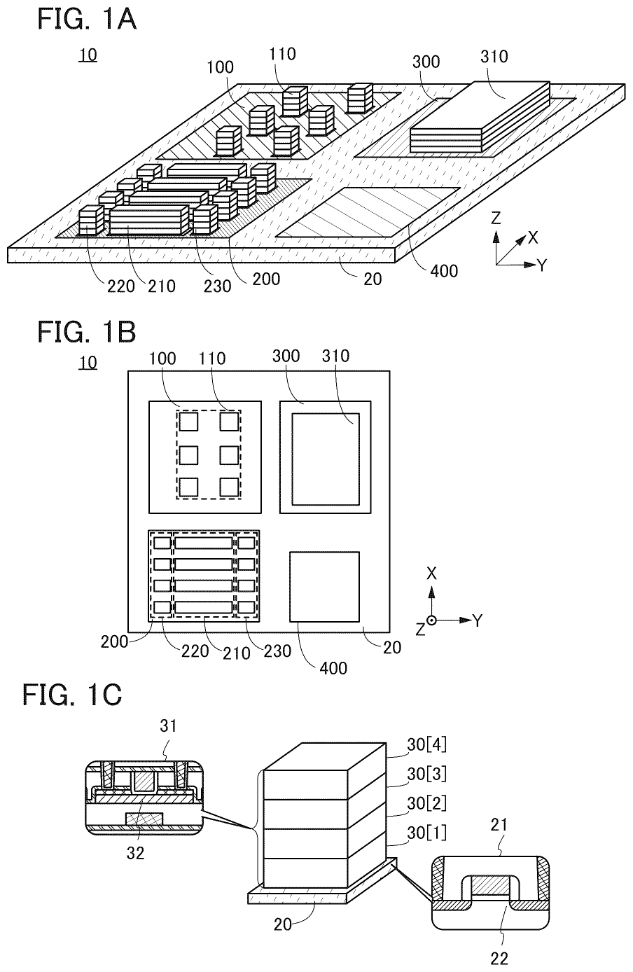

FIG. 1A is a block diagram schematically illustrating a semiconductor device 10 for describing one embodiment of the present invention. FIG. 1B is a block diagram schematically illustrating the top view of the semiconductor device 10. FIG. 1C is a diagram illustrating a structure example of an element layer that can be employed for each of the structures illustrated in FIG. 1A and FIG. 1B.

Note that in this specification and the like, the X direction, the Y direction, and the Z direction may be defined to describe the arrangement of components. For example, in the schematic diagram illustrated in FIG. 1A and FIG. 1B, the X direction, the Y direction, and the Z direction are defined to describe the arrangement of components included in the semiconductor device 10. The X direction, the Y direction, and the Z direction are perpendicular or substantially perpendicular to each other.

In the schematic diagrams illustrated in FIG. 1A and FIG. 1B, components included in the semiconductor device 10 are illustrated apart from each other for easy understanding of the arrangement of components. The components provided in the same layer are preferably formed in the same step; however, one embodiment of the present invention is not limited thereto. For example, a structure may be employed in which components formed in different steps are integrated with a bonding technique or the like.

The semiconductor device 10 illustrated in FIG. 1A and FIG. 1B includes an arithmetic device (also referred to as a first arithmetic device) 100, an arithmetic device (also referred to as a second arithmetic device) 200, a memory device 300, and a peripheral circuit 400.

The semiconductor device 10 illustrated in FIG. 1A and FIG. 1B has a structure in which another element layer (element layer 30) is stacked over an element layer 20. For example, as illustrated in FIG. 1C, the element layers 30 (FIG. 1C illustrates four element layers 30[1] to 30[4]) are stacked over the element layer 20.

In FIG. 1C, a first element layer 30 is denoted by the element layer 30[1], a second element layer 30 is denoted by the element layer 30[2], and a third element layer 30 is denoted by the element layer 30[3]. A k-th (k is an integer greater than or equal to 2) element layer 30 is referred to as an element layer 30[k]. Note that in this embodiment and the like, the “element layer 30” is merely stated in some cases when describing a matter related to all of a plurality of element layers 30 or showing a matter common to the plurality of element layers 30. Similarly, the same applies to a structure denoted by a reference numeral describing a plurality of components.

The arithmetic device 100 has a function of performing general-purpose processing such as execution of an operating system, data control, and execution of various kinds of arithmetic operations and programs, like a CPU. The arithmetic device 100 includes a register 110 having a function of storing data in arithmetic processing.

The arithmetic device 200 includes a plurality of processing elements (PE: a unit of arithmetic processing; also referred to as an arithmetic circuit), and has a function of performing exclusive processing such as image processing or product-sum operation. The arithmetic device 200 includes, in addition to the arithmetic circuit (not illustrated), a memory circuit 210 having a function of storing weight data used for arithmetic processing, and layer selection circuits 220 and 230.

As illustrated in FIG. 1C, the register 110, the memory circuit 210, and the layer selection circuits 220 and 230 each have a structure in which the element layers 30[1] to 30[4] each including a transistor 31 are provided over the element layer 20 including a transistor 21.

The transistor 21 includes silicon in a semiconductor layer 22 including a channel formation region. A transistor including silicon in a semiconductor layer including a channel formation region, like the transistor 21, is referred to as a Si transistor. In the transistor 31, a semiconductor layer 32 including a channel formation region includes an oxide semiconductor. A transistor including an oxide semiconductor in a semiconductor layer including a channel formation region, like the transistor 31, is referred to as an OS transistor.

It is preferable to use, for the Si transistors, silicon with high crystallinity such as single crystal silicon or polycrystalline silicon in order to achieve high field-effect mobility and perform a higher-speed operation.

Examples of a metal oxide used in the OS transistors include indium oxide, gallium oxide, and zinc oxide. The metal oxide preferably contains two or three kinds selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide. Alternatively, it is preferable to use an oxide containing indium, tin, and zinc (also referred to as ITZO). Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO). Further alternatively, it is preferable to use an oxide containing indium (In), gallium (Ga), zinc (Zn), and tin (Sn) (also referred to as IGZTO).

The metal oxide used in the OS transistors may include two or more metal oxide layers with different compositions. For example, a stacked-layer structure of a first metal oxide layer having In:M:Zn=1:3:4 [atomic ratio] or a composition in the vicinity thereof and a second metal oxide layer having In:M:Zn=1:1:1 [atomic ratio] or a composition in the vicinity thereof and being formed over the first metal oxide layer can be suitably employed.

Alternatively, a stacked structure of one selected from indium oxide, indium gallium oxide, and IGZO, and one selected from IAZO, IAGZO, and ITZO may be employed, for example.

The metal oxide used in the OS transistors preferably has crystallinity. Examples of an oxide semiconductor having crystallinity include a CAAC (c-axis-aligned crystalline)-OS and an nc (nanocrystalline)-OS. When the oxide semiconductor having crystallinity is used, the semiconductor device can have high reliability.

The memory device 300 includes a memory layer 310 that stores data which is input to/output from the arithmetic device 100, the arithmetic device 200, and the like.

Note that the memory layer 310 included in the memory device 300 is preferably a NOSRAM, for example. FIG. 1A illustrates the memory layer 310 that is stacked over a driver circuit or the like provided and stacked in the element layer 20 in a manner similar to that of the element layers 30[1] to 30[4]. The memory layer 310 includes a memory cell of a NOSRAM.

NOSRAM (registered trademark) is an abbreviation for “Nonvolatile Oxide Semiconductor Random Access Memory (RAM)”. A NOSRAM is a memory in which its memory cell is a 2-transistor (2T) or 3-transistor (3T) gain cell, and its transistor is an OS transistor. A current flowing between a source and a drain in an off state, that is, a leakage current, is extremely low in an OS transistor. The NOSRAM can be used as a nonvolatile memory by retaining electric charge corresponding to data in the memory cells, using characteristics of extremely low leakage current. In particular, the NOSRAM is capable of reading retained data without destruction (non-destructive reading), and thus is suitable for arithmetic processing in which only a data reading operation is repeated many times. Since the NOSRAM that is provided to have a stacked-layer structure can have large data capacity, when the NOSRAM is used as a large cache memory, a main memory, or a storage memory, the performance of the semiconductor device can be increased.

Note that as a structure applicable to the memory layer 310, a DOSRAM including an OS transistor may be used in addition to the NOSRAM. The DOSRAM (registered trademark) is an abbreviation for “Dynamic Oxide Semiconductor RAM,” which indicates a RAM including a 1T (transistor) 1C (capacitor)-type memory cell. The DOSRAM is a DRAM formed using an OS transistor, and the DOSRAM is a memory that temporarily stores information sent from the outside. The DOSRAM is a memory utilizing a low off-state current of an OS transistor.

Examples of the peripheral circuit 400 include a circuit for interfacing with an external circuit. Examples of the interface circuit include a DRAM (Dynamic Random Access Memory) interface, a PCI (Peripheral Component Interface), a DMA (Direct Memory Access), a network interface, and an audio interface.

The semiconductor device 10 has a function of what is called an SoC, in which the arithmetic devices 100 and 200 such as a CPU and a GPU, the memory device 300, and the like are tightly coupled. With this structure, a wiring connecting the devices that perform data transfer can be shortened, and heat generation and an increase in power consumption can be inhibited.

### Structure Example of Register 110

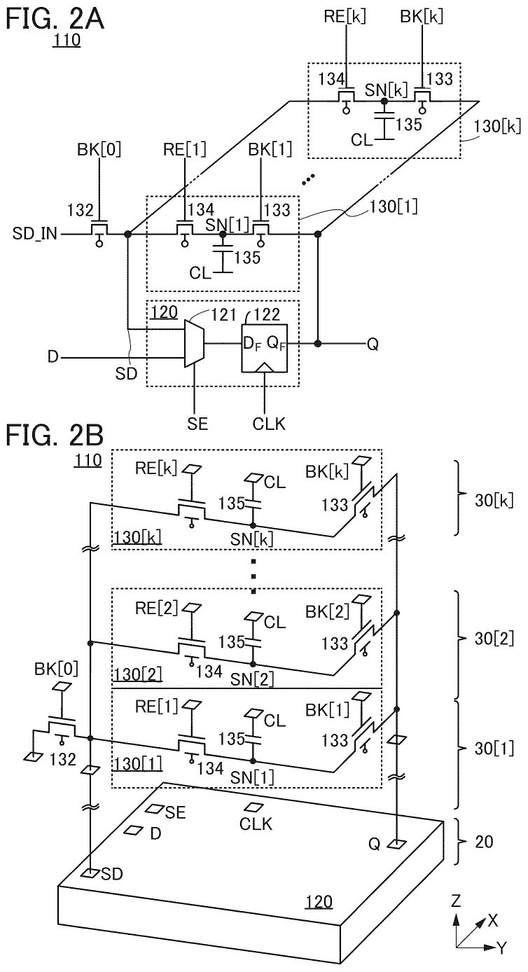

FIG. 2A is a circuit diagram illustrating a structure example of the register 110 illustrated in FIG. 1A and the like. The register 110 includes a scan flip-flop 120 (volatile register) and a plurality of data retention circuits 130[1] to 130[k] (k is an integer greater than or equal to 2). Note that k can be a number corresponding to the number of element layers 30. The scan flip-flop 120 includes a selector 121 and a flip-flop 122. The register 110 includes a transistor 132 as well.

Signals BK[1] to BK[k] are signals that control saving (storing or backing up) of data retained in the flip-flop 122 in the scan flip-flop 120. By the data saving, the data retained in the flip-flop 122 is retained in any one of the data retention circuits 130[1] to 130[k]. The signal BK is also referred to as a backup signal.

Signals RE[1] to RE[k] are signals that control loading (restoring or recovering) of data retained in any one of the data retention circuits 130[1] to 130[k]. By the data loading, the data retained in any one of the data retention circuits 130[1] to 130[k] is retained in the flip-flop 122 in the scan flip-flop 120. The signal RE is also referred to as a restoration signal.

A signal SE is a switch signal for the selector 121. A clock signal CLK is a signal for operating the flip-flop 122.

The register 110 retains data input from a terminal D or data input from a terminal SD of the scan flip-flop 120 in the scan flip-flop 120 and outputs the data from a terminal Q in accordance with the clock signal CLK. Data in the scan flip-flop 120 output from the terminal Q is saved to any one of the data retention circuits 130[1] to 130[k]. Data of any one of the data retention circuits 130[1] to 130[k] is loaded from the terminal SD of the scan flip-flop 120.

The data retention circuits 130[1] to 130[k] can independently save or load data. That is, the scan flip-flop 120 in a plurality of states generated in accordance with switching of the task can be stored in different data retention circuits 130[1] to 130[k].

The scan flip-flop 120 can be formed using a Si transistor. The scan flip-flop 120 can be provided in the element layer 20. The data retention circuits 130[1] to 130[k] can be formed using OS transistors and capacitors. The data retention circuits 130[1] to 130[k] can be respectively provided in the element layers 30[1] to 30[k] each including an OS transistor.

The selector 121 has a function of supplying a signal in the terminal D or the terminal SD to the scan flip-flop 120 in accordance with the signal SE. The terminal D is a terminal that supplies data input from the outside of the register 110. The terminal SD is a terminal that supplies data input from any one of the data retention circuits 130[1] to 130[k] or data input from a terminal SD_IN that supplies data for scan test. Data input from the terminal SD_IN is supplied through the transistor 132 whose conduction state or the non-conduction state is controlled by a signal BK[0].

Although the flip-flop 122 illustrated in FIG. 2A is a D flip-flop, the flip-flop 122 is not limited thereto. A flip-flop prepared in a standard circuit library can be employed. A transistor included in the flip-flop 122 is a Si transistor, and the flip-flop 122 can retain one piece of data by including a circuit such as an inverter loop. The flip-flop 122 retains data in an input terminal DF and outputs the retained data to the terminal Q through an output terminal Q_{F} in accordance with the clock signal CLK.

As described above, the data retention circuits 130[1] to 130[k] are respectively provided in the element layers 30[1] to 30[k] over the element layer 20 where the scan flip-flop 120 is provided. With this structure, the plurality of data retention circuits 130 can be provided within a region where the scan flip-flop 120 is formed; thus, even when the plurality of data retention circuit 130 are incorporated into the register 110, the area overhead of the register 110 can be preferably zero.

In addition, when the data retention circuits 130[1] to 130[k] include a region overlapping with the scan flip-flop 120, the distance between the scan flip-flop 120 and the data retention circuits 130[1] to 130[k] electrically connected to the scan flip-flop 120 can be shortened. Thus, power consumption required for charging and discharging between wirings can be reduced.

Each of the data retention circuits 130[1] to 130[k] includes a transistor 133, a transistor 134, and a capacitor 135. The other electrode of the capacitor 135 is connected to a wiring CL. The transistor 133 is provided between the capacitor 135 and the terminal Q. The transistor 134 is provided between the capacitor 135 and the terminal SD. In each of the plurality of data retention circuits 130[1] to 130[k], one electrode of the capacitor 135 is illustrated as a node SN[1] to a node SN[k].

The transistors 133 and 134 are OS transistors. The transistors 133 and 134 have Back Gates in the illustrated structure. Supplying constant voltages to the Back Gates of the transistors 133 and 134 allows control of transistor characteristics. Because of extremely low off-state currents, which are a feature of the OS transistors, a decrease in the voltages of the nodes SN[1] to SN[k] can be suppressed and almost no electric power is consumed to retain data; therefore, the data retention circuits 130[1] to 130[k] each have nonvolatile characteristics. Data is rewritten by charging and discharging of the capacitors 135; hence, there is theoretically no limitation on rewrite cycles of the data retention circuits 130[1] to 130[k], and data can be written and read out with low energy.

Since all the transistors in the data retention circuits 130[1] to 130[k] are OS transistors, the data retention circuit 130 can be stacked over the scan flip-flop 120 formed using a silicon CMOS circuit as illustrated in FIG. 2B. Note that in FIG. 2B, the transistor 132 is illustrated as being provided in the same layer as the transistor 133 and the transistor 134. The transistor 132 is not limited to an OS transistor. An OS transistor or a Si transistor can be used as the transistor 132.

The number of elements in the data retention circuits 130[1] to 130[k] is much smaller than the number of elements in the scan flip-flop 120; thus, there is no need to change the circuit structure and layout of the scan flip-flop 120 in order to stack the data retention circuits 130[1] to 130[k]. That is, the data retention circuits 130[1] to 130[k] are circuits that have very broad utility. In addition, the data retention circuits 130[1] to 130[k] can be provided within a region where the scan flip-flop 120 is formed; thus, even when the plurality of data retention circuits 130[1] to 130[k] are incorporated, the area overhead can be zero. Since energy required for retaining data in the data retention circuits 130[1] to 130[k] is small, it is possible to frequently save or load data in the arithmetic device 100.

Note that when the data retention circuits 130[1] to 130[k] are provided, parasitic capacitance due to the transistors 133 is added to the node Q; however, the parasitic capacitance is lower than parasitic capacitance due to a logic circuit connected to the node Q and does not affect the operation of the scan flip-flop circuit 120. That is, even when the plurality of data retention circuits 130[1] to 130[k] are provided, the performance of the register 110 does not substantially decrease.

The OS transistors in the data retention circuits 130[1] to 130[k] function as switches. In an OS transistor, which is an n-channel transistor, when a signal supplied to a gate is set to high level (hereinafter expressed as “=“H””), a conduction state (on) can be established between a source and a drain, and when the signal supplied to the gate is set to low level (hereinafter expressed as “=“L””), a non-conduction state (off) can be established between the source and the drain. Furthermore, when the signal SE is set to high level (hereinafter expressed as “=“H””), a signal of the terminal SD is selected in the selector 121, and when the signal SE is set to low level (hereinafter expressed as “=“L””), a signal of the terminal D is selected in the selector 121.

For example, when the signal BK[1]=“H” is set in the data retention circuits 130[1] to 130[k], data retained in the flip-flop 122 can be written to the node SN[1] in the data retention circuit 130[1]. Similarly, when BK[2]=“H”, BK[3]=“H”, and BK[4]=“H” are set, the data in the flip-flop 122 can be written to the node SN[2], the node SN[3], and the node SN[4] in the corresponding data retention circuits 130[2] to 130[4]. Furthermore, when RE[1]=“H” and SE=“H” are set, the data in the node SN[1] of the data retention circuit 130[1] can be written back to the flip-flop 122. Similarly, when RE[2]=“H”, RE[3]=“H”, and RE[4]=“H” are set, the data in the node SN[2], the node SN[3], and the node SN[4] of the corresponding data retention circuits 130[2] to 130[4] can be written back to the flip-flop 122.

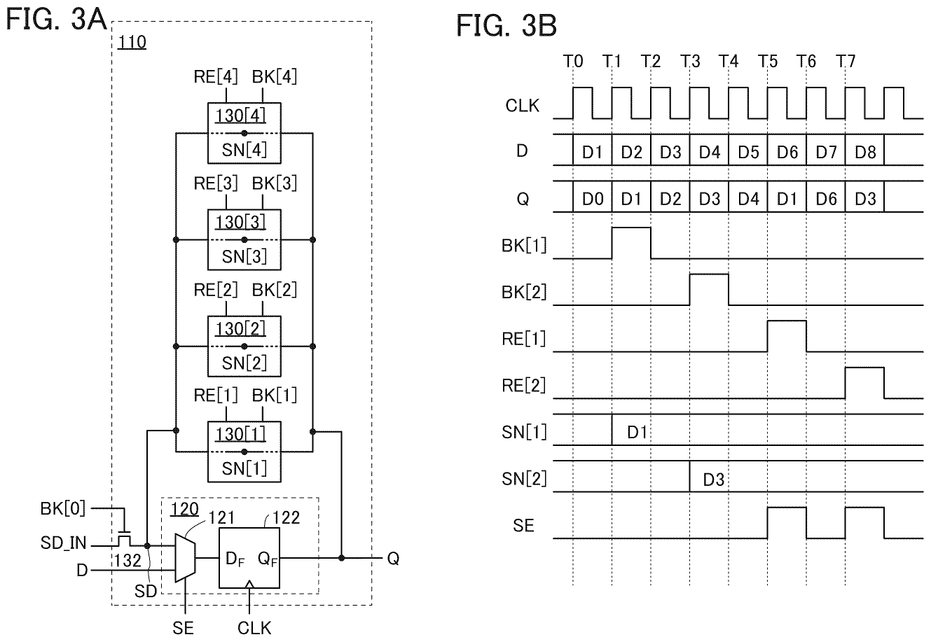

In order to explain the operation of the register 110 described with reference to FIG. 2A, FIG. 3A illustrates a structure at k =4 where four data retention circuit 130 are included in the register 110. In FIG. 3A, the nodes SN[1] to SN[4] that retain data in the data retention circuit 130 (the data retention circuits 130[1] to 130[4]) included in the data retention circuit 130 are illustrated. Furthermore, in FIG. 3A, the signals BK[1] to BK[4] and the signals RE[1] to RE[4] that control the data retention circuits 130[1] to 130[4] are illustrated.

FIG. 3B illustrates an example of a timing chart illustrating the operation of the register 110 illustrated in FIG. 3A. Note that in FIG. 3B, T0 to T7 represent the time. FIG. 3B illustrates the clock signal CLK, the terminal D, the terminal Q, the signal BK[1], the signal BK[2], the signal RE[1], the signal RE[2], the node SN[1], the node SN[2], and the signal SE supplied to the selector 121. The flip-flop 122 stores data of the input terminal DF and performs output from the output terminal Q_{F} in synchronization with a rising edge of the clock signal CLK (a waveform switched from the L level to the H level).

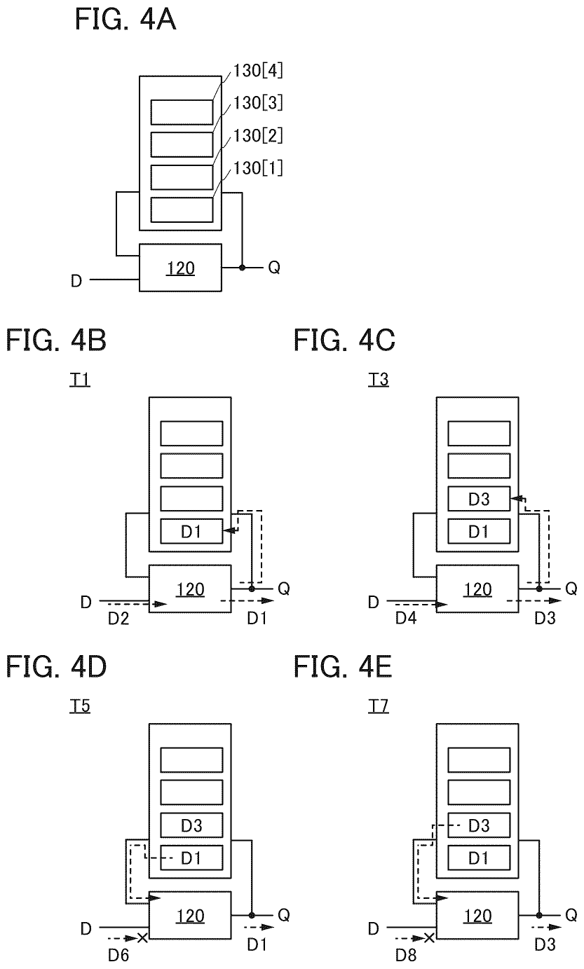

FIG. 4A to FIG. 4E are schematic diagrams of the register 110 for explaining the operation in the timing chart in FIG. 3B. FIG. 4A illustrates the scan flip-flop 120 and the data retention circuits 130[1] to 130[4]. FIG. 4B, FIG. 4C, FIG. 4D, and FIG. 4E are diagrams illustrating data input to and output from the scan flip-flop 120 and the data retention circuits 130[1] to 130[4] at Times T1, T3, T5, and T7 in FIG. 3B.

At Time T0, the scan flip-flop 120 stores data D0 and performs output from the output terminal Q_{F} in synchronization with the rising edge of the clock signal CLK. Data D1 is supplied to the terminal D.

At Time T1, the scan flip-flop 120 stores the data D1 supplied to the terminal D and performs output from the output terminal Q_{F} in synchronization with the rising edge of the clock signal CLK. At Time T1, the signal BK[1]=“H”, the signal RE[1]=“L”, and the signal SE=“L” are set, so that the data D1 in the scan flip-flop 120 is retained in the data retention circuit 130[1] (see FIG. 4B). Data D2 is supplied to the terminal D.

At Time T2, the scan flip-flop 120 stores the data D2 supplied to the terminal D and performs output from the output terminal Q_{F} in synchronization with the rising edge of the clock signal CLK. Data D3 is supplied to the terminal D.

At Time T3, the scan flip-flop 120 stores the data D3 supplied to the terminal D and performs output from the output terminal Q_{F} in synchronization with the rising edge of the clock signal CLK. At Time T3, the signal BK[2]=“H”, the signal RE[2]=“L”, and the signal SE=“L” are set, so that the data D3 in the scan flip-flop 120 is retained in the data retention circuit 130[2] (see FIG. 4C). Data D4 is supplied to the terminal D.

At Time T4, the scan flip-flop 120 stores the data D4 supplied to the terminal D and performs output from the output terminal Q_{F} in synchronization with the rising edge of the clock signal CLK. Data D5 is supplied to the terminal D.

At Time T5, the scan flip-flop 120 stores the data D5 supplied to the terminal D and performs output from the output terminal Q_{F} in synchronization with the rising edge of the clock signal CLK. At Time T5, BK[1]=“L”, RE[1]=“H”, and SE=“H” are set, so that the data D1 retained in the data retention circuit 130[1] can be written back to the scan flip-flop 120 (see FIG. 4D). Data D6 is supplied to the terminal D.

At Time T6, the scan flip-flop 120 stores data D6 supplied to the terminal D and performs output from the output terminal Q_{F} in synchronization with the rising edge of the clock signal CLK. Data D7 is supplied to the terminal D.

At Time T7, the scan flip-flop 120 stores the data D7 supplied to the terminal D and performs output from the output terminal Q_{F} in synchronization with the rising edge of the clock signal CLK. At Time T7, BK[2]=“L”, RE[2]=“H”, and SE=“H” are set, so that the data D3 retained in the data retention circuit 130[2] can be written back to the scan flip-flop 120 (see FIG. 4E). Data D8 is supplied to the terminal D.

As described with reference to FIG. 3B and FIG. 4B to FIG. 4E, a structure of saving the data of the interrupted task and loading the data of the task to be resumed can be formed. In one embodiment of the present invention, the saved data can be stored in the plurality of data retention circuits in accordance with the switch of the task. With this structure, data is saved and loaded in accordance with the switch between a plurality of tasks at the time when an interrupt signal is input, whereby program processing can be sequentially executed. Thus, more efficient data processing can be achieved.

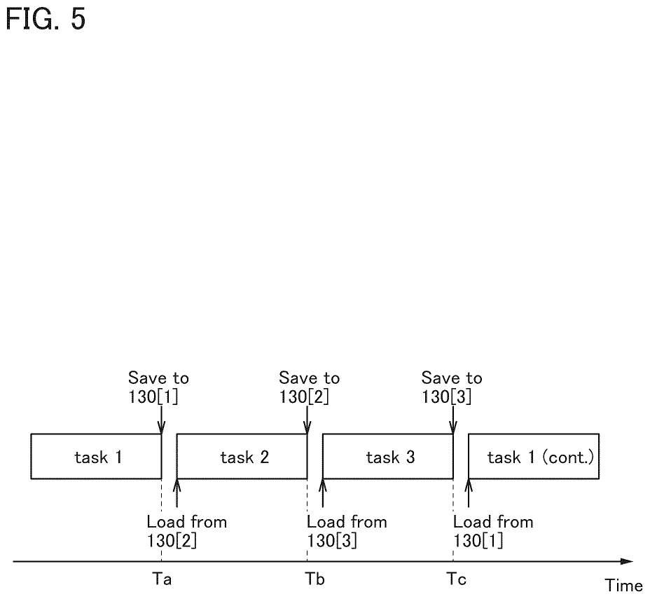

FIG. 5 is a timing chart of a task switching operation utilizing the register 110 illustrated in FIG. 3A and the operation of the register 110 described with reference to FIG. 3B.

At Time Ta with the state where the arithmetic device 100 is executing a task 1, the data in the scan flip-flop 120 is stored in the data retention circuit 130[1] (Save to 130[1]). Then, the data in the data retention circuit 130[2] is written back to the scan flip-flop 120 (Load from 130[2]). In this manner, the state of the task 1 is stored to make a state where execution of a task 2 is possible, and switching to the task 2 is performed.

At Time Tb with the state where the arithmetic device 100 is executing the task 2, the data in the scan flip-flop 120 is stored in the data retention circuit 130[2] (Save to 130[2]). Then, the data in the data retention circuit 130[3] is written back to the scan flip-flop 120 (Load from 130[3]). In this manner, the state of the task 2 is stored to make a state where execution of a task 3 is possible, and switching to the task 3 is performed.

At Time Tc with the state where the arithmetic device 100 is executing the task 3, the data in the scan flip-flop 120 is stored in the data retention circuit 130[3] (Save to 130[3]). Then, the data in the data retention circuit 130[1] is written back to the scan flip-flop 120 (Load from 130[1]). Here, the data written back from the data retention circuit 130[1] to the scan flip-flop 120 is the data stored in the data retention circuit 130[1] from the scan flip-flop 120 at Time Ta. That is, it is possible to execute the task 1 from where the execution was interrupted at Time Ta. In this manner, the state of the task 3 is stored to make a state where execution of the task 1 is possible, and switching to the task 3 is performed.

With the above-described structure, a semiconductor device having an arithmetic device that can reduce power consumption while being provided with a large number of registers can be provided. In addition, a semiconductor device having an arithmetic device with improved computing performance, which can resume the process from where the last execution of the task was interrupted at the time of switching the task, can be provided.

In the arithmetic device, which is provided with the registers and included in the semiconductor device of this embodiment, even after an operation in which program processing by a task is interrupted by another task and further interrupted by another task, processing of the original task can be resumed on the basis of interrupted data. Since the data for resuming the task in the processing is retained in a register inside the arithmetic device, no access to a stack region of an external memory such as an SRAM or a DRAM is required for data saving or loading. Therefore, even when a process of switching to a different task is performed by an interrupt of another task, the data saving or loading process can be performed efficiently without causing a lag of memory access or the like due to the switching.

### Structure Example of Memory Circuit 210 and Layer Selection Circuits 220 and 230

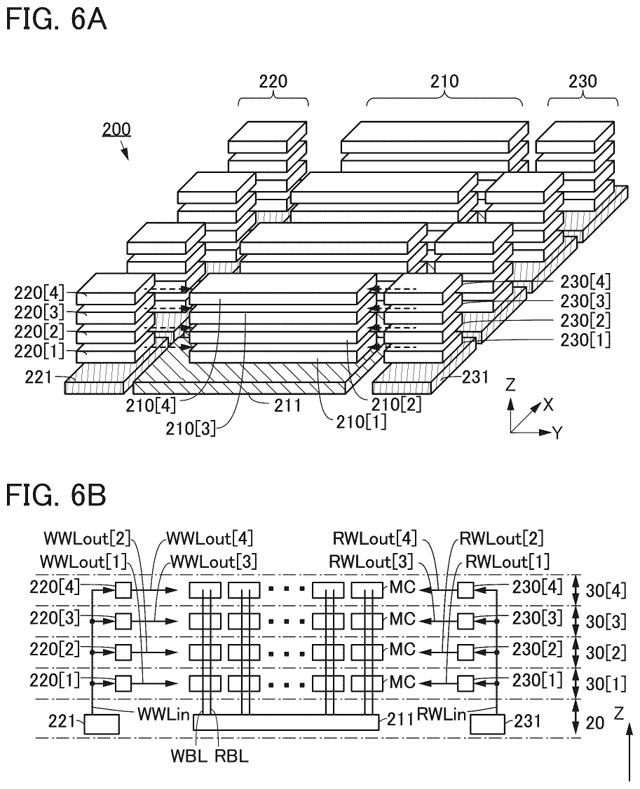

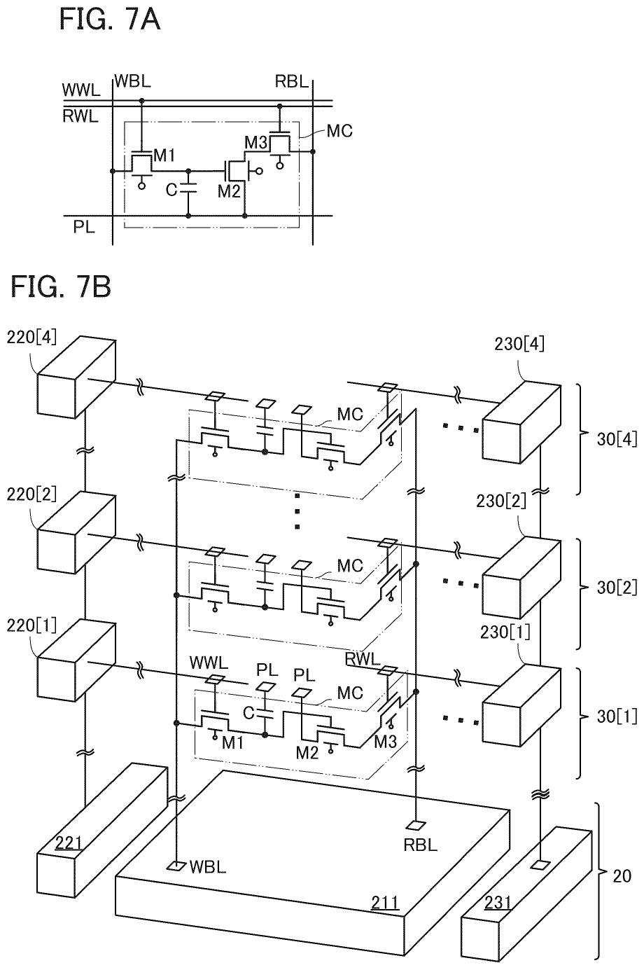

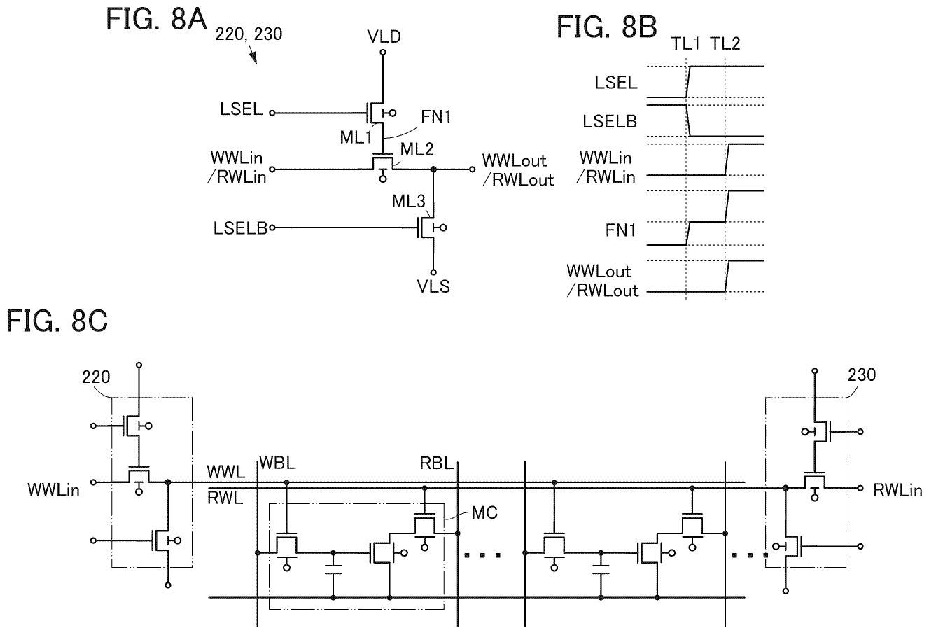

FIG. 6A and FIG. 6B are schematic views each illustrating a structure example of the memory circuit 210 and the layer selection circuits 220 and 230 included in the arithmetic device 200 of one embodiment of the present invention. FIG. 7A and FIG. 7B are diagrams each illustrating a structure example of a memory cell included in the memory circuit 210. FIG. 8A to FIG. 8C are diagrams illustrating circuit structure examples and an operation example of the layer selection circuits 220 and 230. Note that in the following description, for easy understanding, the element layers 30[1] to 30[k] are assumed to be four layers, that is, k=4.

As illustrated in FIG. 6A, a plurality of blocks are illustrated as the memory circuit 210. Note that in FIG. 6A, a block provided with four stacked layers (a block provided with stacked memory circuits 210[1] to 210[4]) corresponds to the memory circuit 210, for example. Note that FIG. 6A illustrates a state where four blocks each provided with four stacked layers are arranged in the X direction.

The memory circuits 210[1] to 210[4] in the element layers respectively include a plurality of memory cells MC provided in the element layers 30[1] to 30[4] (see FIG. 6B).

As the memory cell MC, a memory cell including an OS transistor can be used. For example, a circuit structure example of the NOSRAM illustrated in FIG. 7A can be employed. As the memory cell MC illustrated in FIG. 7A, a NOSRAM including transistors M1 to M3 and a capacitor C is illustrated as an example.

FIG. 7A illustrates a wiring WWL, a wiring RWL, a wiring WBL, a wiring RBL, and a wiring PL connected to the elements included in the memory cell MC. The wiring WWL is a wiring functioning as a write word line. The wiring RWL is a wiring functioning as a read word line. The wiring WBL is a wiring functioning as a write bit line. The wiring RBL is a wiring functioning as a read bit line. The wiring PL is a wiring functioning as a capacitor line. The wiring PL can function as a wiring that supplies a potential to a back gate of the transistor M1.

In the memory cell MC illustrated in FIG. 7A, the memory cells MC electrically connected to the same wiring WBL and the same wiring RBL are arranged in the Y direction in the stacked element layers 30[1] to 30[4] as illustrated in FIG. 7B. FIG. 7B illustrates a schematic view in which the memory cells MC each of which is a NOSRAM including an OS transistor are stacked. When the memory cells MC are arranged and stacked, the memory circuit 210 in which the memory circuits 210[1] to 210[4] illustrated in FIG. 6A are stacked can be obtained.

As illustrated in FIG. 6B and FIG. 7B, the memory cell MC included in each of the memory circuits 210[1] to 210[4] are provided in the same layers as the layer selection circuits 220 and 230 provided in each of the element layers 30[1] to 30[4]. In FIG. 6A, FIG. 6B, and FIG. 7B, the layer selection circuits 220 and 230 provided in the element layers 30[1] to 30[4] are illustrated as layer selection circuits 220[1] to 220[4] and 230[1] to 230[4], respectively.

As illustrated in FIG. 6A, the arithmetic device 200 includes a write word line driver portion 221, a read word line driver portion 231, and an arithmetic circuit 211. Note that FIG. 6B illustrates a state where the write word line driver portion 221, the read word line driver portion 231, and the arithmetic circuit 211 are provided in the element layer 20. The layer selection circuits 220[1] to 220[4] and 230[1] to 230[4] are provided in the element layers 30[1] to 30[4].

In the layer selection circuits 220[1] to 220[4], signals output to wirings WWLout[1] to WWLout[4] are controlled by controlling a signal output to a wiring WWLin from the write word line driver portion 221. The wirings WWLout[1] to WWLout[4] correspond to a wiring WWL connected to the memory cell MC provided in the element layers 30[1] to 30[4]. The signals output to the wirings WWLout[1] to WWLout[4] are signals for controlling writing of data signals from the wiring WBL provided to extend in the Z direction to the memory cell MC. The layer selection circuits 220[1] to 220[4] can be provided to overlap with each other in the Z direction as illustrated in FIG. 6A and FIG. 6B.

In the layer selection circuits 230[1] to 230[4], output of signals to wirings RWLout[1] to RWLout[4] are controlled by controlling a signal output to a wiring RWLin from the read word line driver portion 231. The wirings RWLout[1] to RWLout[4] correspond to the wiring RWL connected to the memory cell MC provided in the element layers 30[1] to 30[4]. The signals output to the wirings RWLout[1] to RWLout[4] are signals for controlling reading of data signals from the wiring RBL provided to extend in the Z direction to the memory cells MC. The layer selection circuits 230[1] to 230[4] can be provided to overlap with each other in the Z direction as illustrated in FIG. 6A, FIG. 6B, and FIG. 7B.

FIG. 8A is a circuit diagram illustrating a circuit structure example applicable to the layer selection circuits 220 and 230. The layer selection circuits 220 and 230 each include a transistor ML1, a transistor ML2, and a transistor ML3. Each of the transistor ML1 to the transistor ML3 is an OS transistor which is provided in the stacked element layers 30[1] to 30[4], like the transistor included in the memory cell MC.

A gate of the transistor ML2 is electrically connected to one of a source and a drain of the transistor ML1. One of a source and a drain of the transistor ML2 is electrically connected to one of a source and a drain of the transistor ML3 and a wiring WWLout or a wiring RWLout (WWLout/RWLout in the drawing) that corresponds to the wiring WWL or the wiring RWL provided in the element layers 30[1] to 30[4]. The other of the source and the drain of the transistor ML2 is electrically connected to the wiring WWLin or the wiring RWLin (WWLin or RWLin in the drawing) connected to the write word line driver portion 221 or the read word line driver portion 231. The other of the source and the drain of the transistor ML1 is electrically connected to a wiring to which a potential VLD (high power supply potential) is supplied. A gate of the transistor ML1 is electrically connected to a wiring to which a signal LSEL is supplied. A gate of the transistor ML3 is electrically connected to a wiring to which a signal LSELB is supplied. The other of the source and the drain of the transistor ML3 is electrically connected to a wiring to which a potential VLS (low power supply potential) is supplied. Note that a region where the gate of the transistor ML2 and the one of the source and the drain of the transistor ML1 are electrically connected to each other is referred to as a node FN1 in some cases.

FIG. 8C illustrates a structure example of the plurality of memory cells MC connected to the layer selection circuits 220 and 230 through the wiring WWL and the wiring RWL. The plurality of memory cells MC illustrated in FIG. 8C are collectively selected by signals output from the layer selection circuits 220 and 230. Thus, by controlling signals output from the layer selection circuits 220 and 230, data can be collectively written to and read from the memory circuit 210 provided in each element layer 30.

Note that the structures of the layer selection circuits 220 and 230 are not limited to the structure example illustrated in FIG. 8A. For example, a capacitor may be provided between the gate of the transistor ML2 and the one of the source and the drain of the transistor ML1.

The layer selection circuits 220 and 230 have a function of outputting, to the wiring WWLout or the wiring RWLout, any of a signal supplied to the wiring WWLin or the wiring RWLin or a potential VLS in accordance with the signal LSEL and the signal LSELB.

FIG. 8B is a timing chart illustrating an operation example of the layer selection circuits 220 and 230.

The timing chart in FIG. 8B illustrates potentials (H level and L level) of the signal LSEL, the signal LSELB, and the signal supplied to the wiring WWLin or the wiring RWLin at each operation time. In addition, changes in potentials of the node FN1, the wiring WWLout, and the wiring RWLout are shown.

Note that in the following description of the operation example, the potential VLD is assumed to be equal to the H level of the signal LSEL and the signal LSELB. The potential VLS is assumed to be equal to the L level of the signal LSEL and the signal LSELB.

Immediately before Time TL1, the signal LSEL is set to the L level and the signal LSELB is set to the H level. At this time, since the transistor ML1 is in a conduction state, the potential of the node FN1 becomes the L level. Thus, the transistor ML2 is in a non-conduction state and the transistor ML3 is in a conduction state. Thus, the potential of the wiring WWLout or the wiring RWLout becomes the L level (potential VLS) regardless of whether the signal supplied to the wiring WWLin or the wiring RWLin is at the H level or the L level.

At Time TL1, the signal LSEL is brought to the H level and the signal LSELB is brought to the L level. At this time, the potential of the node FN1 increases to a potential obtained by subtracting a threshold voltage of the transistor ML1 from the H level (the potential VLD), and the transistor ML1 is brought to a non-conduction state. Then, the transistor ML2 is brought to a conduction state and the transistor ML3 is brought to a non-conduction state. Thus, the potential of the wiring WWLout or the wiring RWLout becomes the L level (a signal supplied to the wiring WWLin or the wiring RWLin at Time TL1).

At Time TL2, the signal supplied to the wiring WWLin or the wiring RWLin is brought to the H level. Then, current flows from the wiring WWLin or the wiring RWLin to the wiring WWLout or the wiring RWLout through the transistor ML2, whereby the potential of the wiring WWLout or the wiring RWLout increases. At this time, since the transistor ML1 is in a non-conduction state, the potential of the node FN1 also increases owing to capacitive coupling by the gate capacitance of the transistor ML2. Thus, a potential difference between the gate and the source of the transistor ML2 is maintained, that is, the conduction state of the transistor ML2 is maintained. Thus, the potential of the wiring WWLout or the wiring RWLout becomes the H level (a signal supplied to the wiring WWLin or the wiring RWLin at Time TL2).

In this manner, the layer selection circuits 220 and 230 form a bootstrap circuit provided with a gate capacitance between the gate and the source of the transistor ML2, whereby the conduction state of the transistor ML2 is maintained when the signal supplied to the wiring WWLin or the wiring RWLin becomes the H level; thus, the H level can be output to the wiring WWLout or the wiring RWLout. Note that the gate capacitance of the transistor ML2 is referred to as a “bootstrap capacitance” in some cases.

The arithmetic device 200 can select any one of the memory circuits 210[1] to 210[4] and output the signal supplied to the wiring WWLin or the wiring RWLin to the wiring WWLout or the wiring RWLout by controlling the signal LSEL and the signal LSELB supplied to the layer selection circuits 220[1] to 220[4] or the layer selection circuits 230[1] to 230[4].

For example, when the signal LSEL and the signal LSELB supplied to the layer selection circuit 220[1] are set to the H level and the L level, respectively, and the signal LSEL and the signal LSELB supplied to the layer selection circuits 220[2] to 220[4] are set to the L level and the H level, respectively, a signal supplied from the write word line driver portion 221 to the wiring WWLin is output to the wiring WWLout[1] through the layer selection circuit 220[1].

In the arithmetic device 200, a wiring functioning as a word line needs to be provided in each of the element layers 30[1] to 30[4] from the element layer 20; however, the number of wirings can be reduced by providing a layer selection circuit in each element layer. The arithmetic device 200 can suppress an increase in areas of the write word line driver portion 221 and the read word line driver portion 231 due to an increase in the number of element layers 30[1] to 30[4]. That is, in the arithmetic device 200, the number of element layers 30[1] to 30[4] provided with memory circuits can be increased without an increase in area overhead, so that the density of the memory cell MC (memory density) can be increased.

Next, a structure example of the arithmetic circuit 211 will be described. The arithmetic circuit 211 has a function of performing product-sum operation. The arithmetic device 200 including the arithmetic circuit 211 is referred to as an accelerator or a GPU (Graphics Processing Unit) in some cases. The memory cell MC such as a NOSRAM or a DOSRAM can be stacked over the arithmetic circuit 211. That is, a layer including OS transistors can be stacked in the direction perpendicular to the substrate over which the element layer 20 including a Si transistor is provided.

The arithmetic circuit 211 can perform parallel processing of matrix operation in graphics processing, parallel processing of product-sum operation of a neural network, and parallel processing of floating-point operation in a scientific computation, for example.

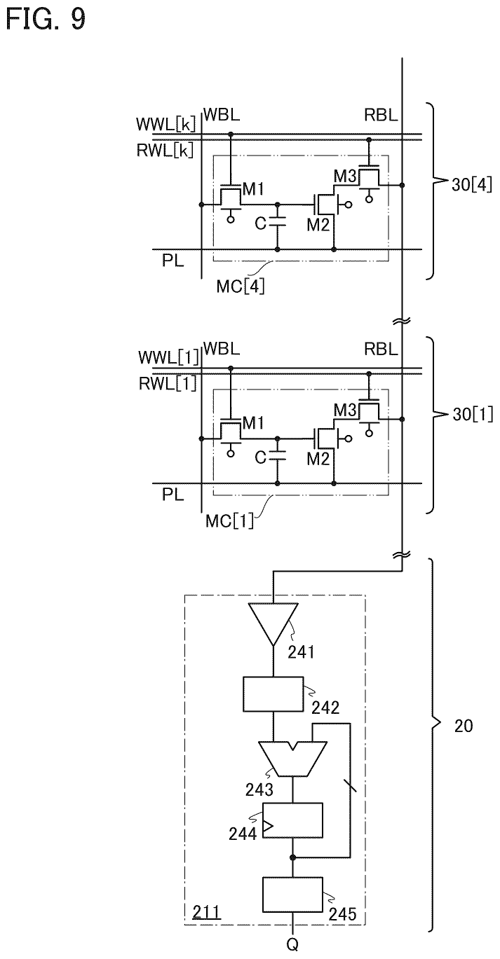

For example, for each of memory cells MC[1] to MC[4] illustrated in FIG. 9, a memory cell including an OS transistor, such as a NOSRAM, can be used. The circuit structure of the memory cells MC[1] to MC[4] illustrated in FIG. 9 corresponds to a NOSRAM of a 3-transistor (3T) gain cell. The NOSRAM can be used as a nonvolatile memory by retaining electric charge corresponding to data in the memory cells, using characteristics of extremely low leakage current.

For example, the arithmetic circuit 211 illustrated in FIG. 9 includes a readout circuit 241 supplied with a signal of the wiring RBL, a bit product-sum operation unit 242, an accumulator 243, a latch circuit 244, and an encoding circuit 245 for outputting an output signal Q.

Each circuit included in the arithmetic circuit 211 includes a Si transistor and can be provided in the element layer 20. The memory cell MC includes an OS transistor and can be provided in the element layers 30[1] to 30[4]. Thus, as illustrated in FIG. 7A and FIG. 7B, in the structure in which the element layer 20 and the element layers 30[1] to 30[4] are stacked, regions where the circuits are provided can be provided to overlap with each other. The wiring RBL that connects the arithmetic circuit 211 and the memory cell MC is provided in the direction perpendicular to the surface of the substrate provided with the element layer 20 (the z direction). The wiring RWL is a wiring that can be provided in an opening portion provided in an insulating layer, and microfabrication of the wiring RWL is possible. Therefore, the wiring RWL can cause smaller parasitic capacitance than a wiring or the like using a through silicon via or the like. As a result, electric power required for charging and discharging of the wiring can be reduced and power can be saved.

The circuit area can be reduced by the circuit structure specialized for the product-sum operation illustrated in FIG. 9. Thus, power consumption can be reduced owing to a reduction in circuit area.

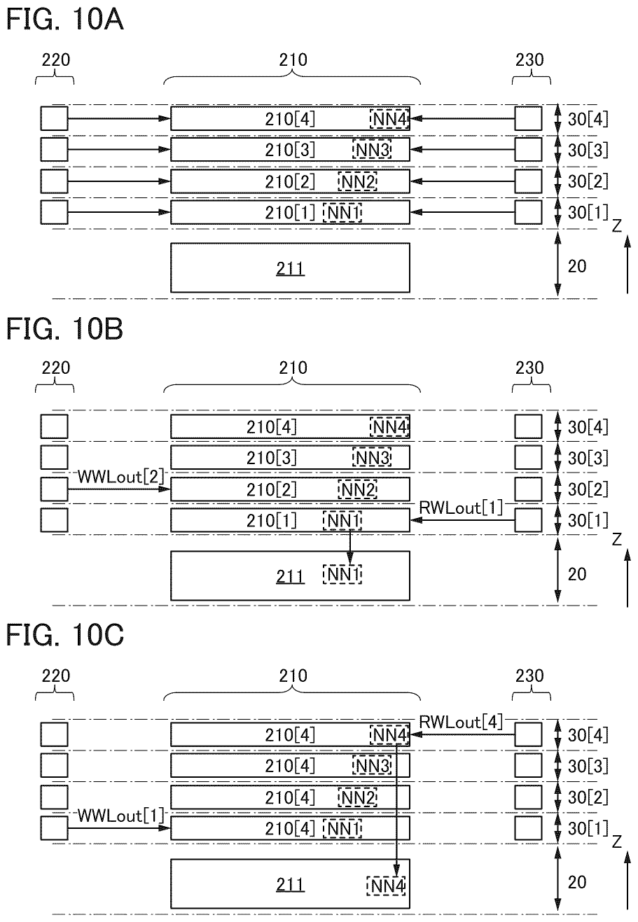

FIG. 10A to FIG. 10C are schematic diagrams illustrating a structure in which different data is stored in the memory circuit 210 provided in each of the plurality of element layers 30[1] to 30[4] and the data is read out or written by switching between the layer selection circuits.

In the memory circuit 210, data stored in each element layer 30 is weight data used for product-sum operation. FIG. 10A illustrates a state where weight data NN1 is stored in the memory circuit 210[1] included in the element layer 30[1], which is a first layer. FIG. 10A illustrates a state where weight data NN2 is stored in the memory circuit 210[2] included in the element layer 30[2], which is a second layer. FIG. 10A illustrates a state where weight data NN3 is stored in the memory circuit 210[3] included in the element layer 30[3], which is a third layer. FIG. 10A illustrates a state where weight data NN4 is stored in the memory circuit 210[4] included in the element layer 30[4], which is a fourth layer.

The data set of weight data stored in the memory circuits 210[1] to 210[4] is written from the arithmetic circuit 211 to the memory cell MC in each of the memory circuit 210 by switching between the layer selection circuits 220. The weight data is read from the memory cell MC in each of the memory circuit 210 to the arithmetic circuit 211 by switching between the layer selection circuits 230.

For example, in FIG. 10B, the weight data NN2 of the memory circuit 210[2] can be updated by controlling the layer selection circuit 220 to output a signal to the wiring WWLout[2]. For example, in FIG. 10B, the weight data NN1 of the memory circuit 210[1] can be read out to the arithmetic circuit 211 by controlling the layer selection circuit 230 to output a signal to the wiring RWLout[1].

In FIG. 10C, the weight data NN1 of the memory circuit 210[1] can be updated by controlling the layer selection circuit 220 to output a signal to the wiring WWLout[1]. For example, in FIG. 10C, the weight data NN4 of the memory circuit 210[4] can be read out to the arithmetic circuit 211 by controlling the layer selection circuit 230 to output a signal to the wiring RWLout[4].

As illustrated in FIG. 10B and FIG. 10C, the weight data can be written to and read out from the different memory circuit 210 by controlling the layer selection circuits 220 and 230. That is, with such a structure, the sequence of switching weight data can be performed by switching the layer selection circuits 220 and 230 in arithmetic processing that imitates a neural network.

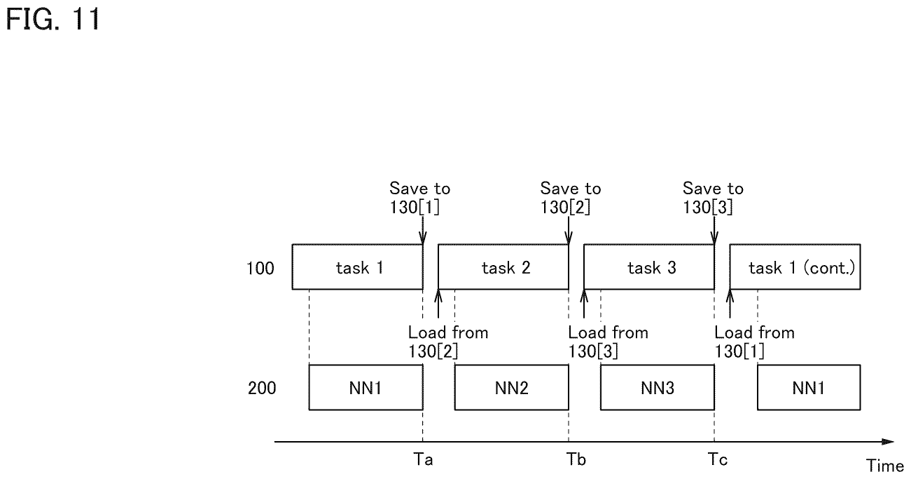

FIG. 11 is a timing chart for describing a state where switching of tasks in the arithmetic device 100 described with reference to FIG. 6 and switching of weight data in arithmetic processing that imitates a neural network in the arithmetic device 200 are performed simultaneously.

At Time Ta with the state where the arithmetic device 100 is executing the task 1, the data in the scan flip-flop 120 is stored in the data retention circuit 130[1] (Save to 130[1]). Then, the data in the data retention circuit 130[2] is written back to the scan flip-flop 120 (Load from 130[2]). In this manner, the state of the task 1 is stored to make a state where execution of the task 2 is possible, and switching to the task 2 is performed. At the same time, the arithmetic device 200 reads out the weight data NN2 from the memory cell of the memory circuit 210[2], and switching is performed from arithmetic processing based on a first neural network to arithmetic processing based on a second neural network.

At Time Tb with the state where the arithmetic device 100 is executing the task 2, the data in the scan flip-flop 120 is stored in the data retention circuit 130[2] (Save to 130[2]). Then, the data in the data retention circuit 130[3] is written back to the scan flip-flop 120 (Load from 130[3]). In this manner, the state of the task 2 is stored to make a state where execution of the task 3 is possible, and switching to the task 3 is performed. At the same time, the arithmetic device 200 reads out the weight data NN3 from the memory cell of the memory circuit 210[3], and switching is performed from arithmetic processing based on the second neural network to arithmetic processing based on a third neural network.

At Time Tc with the state where the arithmetic device 100 is executing the task 3, the data in the scan flip-flop 120 is stored in the data retention circuit 130[3] (Save to 130[3]). Then, the data in the data retention circuit 130[1] is written back to the scan flip-flop 120 (Load from 130[1]). Here, the data written back from the data retention circuit 130[1] to the scan flip-flop 120 is the data stored in the data retention circuit 130[1] from the scan flip-flop 120 at Time Ta. That is, it is possible to execute the task 1 from where the execution was interrupted at Time Ta. In this manner, the state of the task 3 is stored to make a state where execution of the task 1 is possible, and switching to the task 3 is performed. At the same time, the arithmetic device 200 reads out the weight data NN1 from the memory cell of the memory circuit 210[1], and switching is performed from arithmetic processing based on the third neural network to arithmetic processing based on the first neural network.

For example, the first neural network can perform numerical recognition and execute number authentication as a first task. The second neural network can perform animal recognition and confirm the location of a pet as a second task. The third neural network can perform vehicle recognition and confirm the presence or absence of a visitor as a third task.

With the above-described structure, a semiconductor device that can reduce power consumption while being provided with a large number of registers can be provided. In addition, a semiconductor device with improved computing performance, which can resume the process from where the last execution of the task was interrupted at the time of switching the task, can be provided. Furthermore, a semiconductor device that is compatible with a plurality of neural networks and has improved computing performance can be provided.

This embodiment can be implemented in combination with the other embodiments described in this specification as appropriate.

### Embodiment 2

In this embodiment, structures of transistors that can be used in the semiconductor device described in the above embodiment will be described. As an example, a structure in which transistors having different electrical characteristics are stacked will be described. With this structure, the degree of freedom in design of a semiconductor device can be increased. In addition, providing transistors having different electrical characteristics to be stacked can increase the integration degree of the semiconductor device.

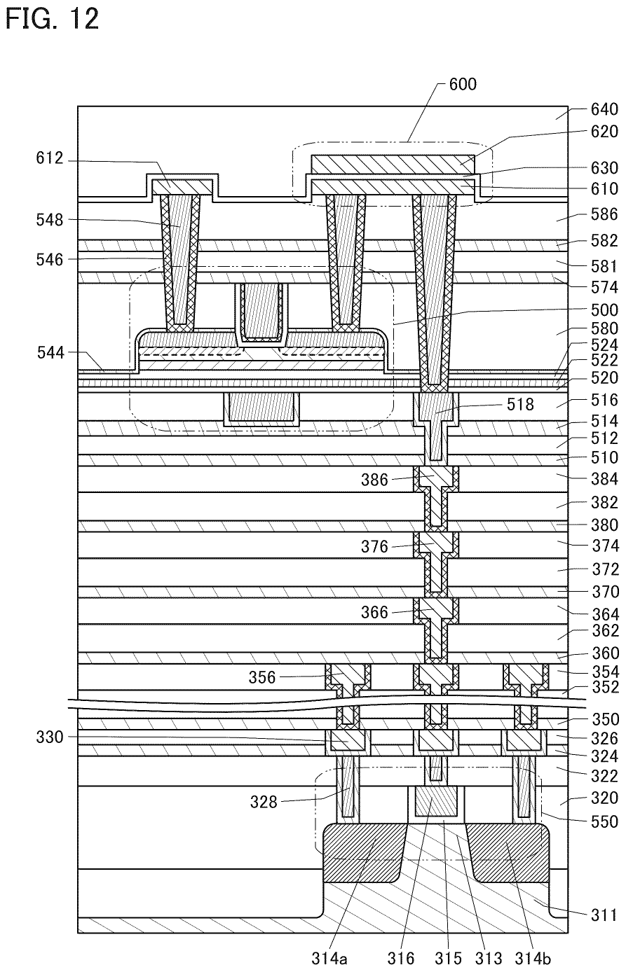

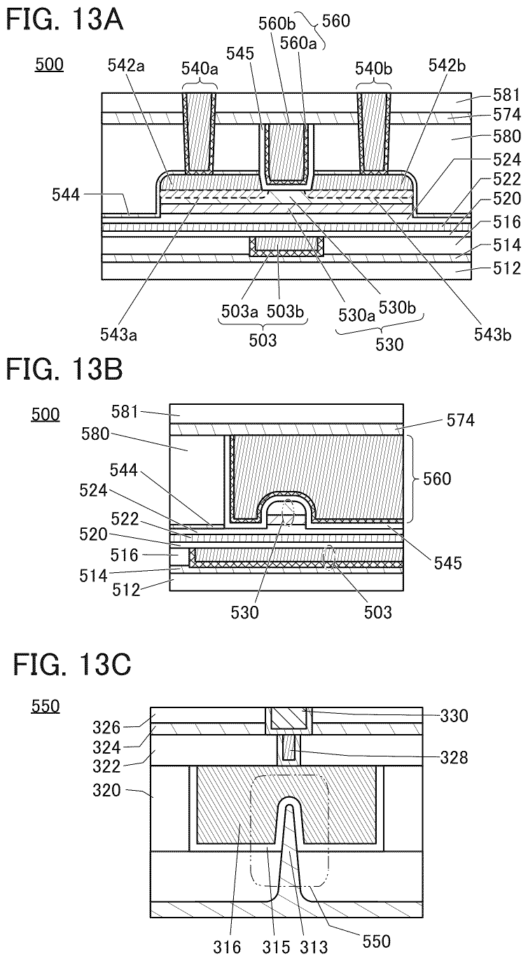

FIG. 12 illustrates part of a cross-sectional structure of a semiconductor device. The semiconductor device illustrated in FIG. 12 includes a transistor 550, a transistor 500, and a capacitor 600. FIG. 13A is a cross-sectional view of the transistor 500 in the channel length direction, FIG. 13B is a cross-sectional view of the transistor 500 in the channel width direction, and FIG. 13C is a cross-sectional view of the transistor 550 in the channel width direction. For example, the transistor 500 corresponds to the Si transistor described in the above embodiment, and the transistor 550 corresponds to the OS transistor.

In FIG. 12, the transistor 500 is provided above the transistor 550, and the capacitor 600 is provided above the transistor 550 and the transistor 500.

The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 13C, the top surface and the side surface in the channel width direction of the semiconductor region 313 of the transistor 550 are covered with the conductor 316 with the insulator 315 positioned therebetween. Such a Fin-type transistor 550 can have an increased effective channel width and thus have improved on-state characteristics. In addition, contribution of the electric field of a gate electrode can be increased, so that the off-state characteristics of the transistor 550 can be improved.

Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably include a semiconductor such as a silicon-based semiconductor, and preferably include single crystal silicon. Alternatively, the regions may be formed using a material containing Ge (germanium), SiGe (silicon germanium), GaAs (gallium arsenide), GaAlAs (gallium aluminum arsenide), or the like. A structure using silicon whose effective mass is controlled by applying stress to a crystal lattice and changing lattice spacing may be employed. Alternatively, the transistor 550 may be a HEMT (High Electron Mobility Transistor) using GaAs and GaAlAs or the like.

The low-resistance region 314a and the low-resistance region 314b include an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, it is possible to use a semiconductor material such as silicon containing the element that imparts n-type conductivity, such as arsenic or phosphorus, or the element that imparts p-type conductivity, such as boron, or a conductive material such as a metal material, an alloy material, or a metal oxide material.

Note that since a work function depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (Silicon on Insulator) substrate or the like

As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature heating, and an SOI substrate formed by a Smart-Cut method in which a semiconductor substrate is cleaved by utilizing growth of a minute void, which is formed by implantation of a hydrogen ion, by heat treatment; an ELTRAN method (registered trademark: Epitaxial Layer Transfer); or the like. A transistor formed using a single crystal substrate includes a single crystal semiconductor in a channel formation region.

An insulator 320, an insulator 322, an insulator 324, and an insulator 326 are sequentially stacked and provided to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, the top surface of the insulator 322 may be planarized by planarization treatment using a chemical mechanical polishing (CMP) method or the like to have improved planarity.

For the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, silicon nitride deposited by a CVD method can be used, for example. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. The film that inhibits hydrogen diffusion is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm₂, preferably less than or equal to 5×10¹⁵ atoms/cm², in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for the interlayer film, parasitic capacitance generated between wirings can be reduced.

A conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each have a function of a plug or a wiring. A plurality of conductors functioning as plugs or wirings are collectively denoted by the same reference numeral in some cases. In this specification and the like, a wiring and a plug connected to the wiring may be a single component. That is, part of a conductor functions as a wiring in some cases and part of the conductor functions as a plug in other cases.

As a material for each of the plugs and wirings (the conductor 328, the conductor 330, and the like), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, an insulator 350, an insulator 352, and an insulator 354 are stacked sequentially in FIG. 12. Furthermore, a conductor 356 is formed in the insulator 350, the insulator 352, and the insulator 354. The conductor 356 has a function of a plug or a wiring that is connected to the transistor 550. Note that the conductor 356 can be formed using a material similar to that for the conductor 328 and the conductor 330.

Note that for example, the insulator 350 is preferably formed using an insulator having a barrier property against hydrogen, like the insulator 324. Furthermore, the conductor 356 preferably includes a conductor having a barrier property against hydrogen. The conductor having a barrier property against hydrogen is formed particularly in an opening portion of the insulator 350 having a barrier property against hydrogen. With this structure, the transistor 550 and the transistor 500 can be separated with a barrier layer, so that hydrogen diffusion from the transistor 550 into the transistor 500 can be inhibited.

Note that for the conductor having a barrier property against hydrogen, tantalum nitride or the like is preferably used, for example. By stacking tantalum nitride and tungsten, which has high conductivity, diffusion of hydrogen from the transistor 550 can be inhibited while the conductivity as a wiring is kept. In that case, a tantalum nitride layer having a barrier property against hydrogen is preferably in contact with the insulator 350 having a barrier property against hydrogen.

A wiring layer may be provided over the insulator 354 and the conductor 356. For example, an insulator 360, an insulator 362, and an insulator 364 are stacked sequentially in FIG. 12. Furthermore, a conductor 366 is formed in the insulator 360, the insulator 362, and the insulator 364. The conductor 366 has a function of a plug or a wiring. Note that the conductor 366 can be formed using a material similar to that for the conductor 328 and the conductor 330.

Note that for example, the insulator 360 is preferably formed using an insulator having a barrier property against hydrogen, like the insulator 324. Furthermore, the conductor 366 preferably includes a conductor having a barrier property against hydrogen. The conductor having a barrier property against hydrogen is formed particularly in an opening portion of the insulator 360 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 364 and the conductor 366. For example, an insulator 370, an insulator 372, and an insulator 374 are stacked sequentially in FIG. 12. Furthermore, a conductor 376 is formed in the insulator 370, the insulator 372, and the insulator 374. The conductor 376 has a function of a plug or a wiring. Note that the conductor 376 can be formed using a material similar to that for the conductor 328 and the conductor 330.

Note that for example, the insulator 370 is preferably formed using an insulator having a barrier property against hydrogen, like the insulator 324. Furthermore, the conductor 376 preferably includes a conductor having a barrier property against hydrogen. The conductor having a barrier property against hydrogen is formed particularly in an opening portion of the insulator 370 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 374 and the conductor 376. For example, an insulator 380, an insulator 382, and an insulator 384 are stacked sequentially in FIG. 12. Furthermore, a conductor 386 is formed in the insulator 380, the insulator 382, and the insulator 384. The conductor 386 has a function of a plug or a wiring. Note that the conductor 386 can be formed using a material similar to that for the conductor 328 and the conductor 330.

Note that for example, the insulator 380 is preferably formed using an insulator having a barrier property against hydrogen, like the insulator 324. Furthermore, the conductor 386 preferably includes a conductor having a barrier property against hydrogen. The conductor having a barrier property against hydrogen is formed particularly in an opening portion of the insulator 380 having a barrier property against hydrogen. With this structure, the transistor 550 and the transistor 500 can be separated with a barrier layer, so that hydrogen diffusion from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device of this embodiment is not limited thereto. The number of wiring layers similar to the wiring layer including the conductor 356 may be three or less, or five or more.

An insulator 510, an insulator 512, an insulator 514, and an insulator 516 are stacked sequentially over the insulator 384. A substance having a barrier property against oxygen, hydrogen, or the like is preferably used for any of the insulator 510, the insulator 512, the insulator 514, and the insulator 516.

For example, for each of the insulator 510 and the insulator 514, it is preferable to use a film having a barrier property that prevents diffusion of hydrogen, impurities, or the like from the substrate 311, a region where the transistor 550 is provided, or the like into a region where the transistor 500 is provided. Thus, a material similar to that for the insulator 324 can be used.

For the film having a barrier property against hydrogen, silicon nitride deposited by a CVD method can be used, for example. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. The film that inhibits hydrogen diffusion is specifically a film from which a small amount of hydrogen is released.

For the film having a barrier property against hydrogen used for each of the insulator 510 and the insulator 514, for example, a metal oxide such as aluminum oxide, hafnium oxide, or tantalum oxide is preferably used.

In particular, aluminum oxide has an excellent blocking effect that prevents passage of both oxygen and impurities such as hydrogen and moisture that cause a change in electrical characteristics of the transistor. Accordingly, the use of aluminum oxide can prevent entry of impurities such as hydrogen and moisture into the transistor 500 during and after a fabrication process of the transistor. In addition, release of oxygen from the oxide included in the transistor 500 can be inhibited. Thus, aluminum oxide is suitably used for a protective film of the transistor 500.

The insulator 512 and the insulator 516 can be formed using a material similar to that for the insulator 320, for example. In the case where a material with relatively low permittivity is used for these insulators, the parasitic capacitance between wirings can be reduced. A silicon oxide film, a silicon oxynitride film, or the like can be used for the insulator 512 and the insulator 516, for example.

A conductor 518, a conductor included in the transistor 500 (e.g., a conductor 503), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be formed using a material similar to that for the conductor 328 and the conductor 330.

In particular, the conductor 518 in a region in contact with the insulator 510 and the insulator 514 is preferably a conductor having a barrier property against oxygen, hydrogen, and water. With this structure, the transistor 550 and the transistor 500 can be separated with a layer having a barrier property against oxygen, hydrogen, and water, so that hydrogen diffusion from the transistor 550 into the transistor 500 can be inhibited.

The transistor 500 is provided over the insulator 516.

As illustrated in FIG. 13A and FIG. 13B, the transistor 500 includes the conductor 503 placed to be embedded in the insulator 514 and the insulator 516, an insulator 520 placed over the insulator 516 and the conductor 503, an insulator 522 placed over the insulator 520, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and has an opening overlapping with an area between the conductor 542a and the conductor 542b, an insulator 545 placed on the bottom surface and a side surface of the opening, and a conductor 560 that is placed on the formation surface of the insulator 545.

As illustrated in FIG. 13A and FIG. 13B, an insulator 544 is preferably placed between the insulator 580 and the oxide 530a, the oxide 530b, the conductor 542a, and the conductor 542b. In addition, as illustrated in FIG. 13A and FIG. 13B, the conductor 560 preferably includes a conductor 560a provided inside the insulator 545 and a conductor 560b provided to be embedded inside the conductor 560a. Moreover, as illustrated in FIG. 13A and FIG. 13B, an insulator 574 is preferably placed over the insulator 580, the conductor 560, and the insulator 545.

Note that in this specification and the like, the oxide 530a and the oxide 530b may be collectively referred to as an oxide 530.

Note that the transistor 500 is illustrated to have a structure in which two layers, the oxide 530a and the oxide 530b, are stacked in the region where the channel is formed and its vicinity; however, the present invention is not limited thereto. For example, a single layer of the oxide 530b or a stacked-layer structure of three or more layers may be provided.

Although the conductor 560 has a two-layer structure in the transistor 500, the present invention is not limited thereto. For example, the conductor 560 may have a single-layer structure or a stacked-layer structure of three or more layers. The transistor 500 illustrated in FIG. 12 and FIG. 13A is just an example and is not limited to the structure illustrated therein, and an appropriate transistor can be used in accordance with a circuit structure, a driving method, or the like.

Here, the conductor 560 functions as a gate electrode of the transistor, and the conductor 542a and the conductor 542b each function as a source electrode or a drain electrode. As described above, the conductor 560 is formed to be embedded in an opening of the insulator 580 and the region sandwiched between the conductor 542a and the conductor 542b. conductor The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Therefore, the conductor 560 can be formed without an alignment margin, resulting in a reduction in the area occupied by the transistor 500. Accordingly, miniaturization and high integration of the semiconductor device can be achieved.

Since the conductor 560 is formed in the region between the conductor 542a and the conductor 542b in a self-aligned manner, the conductor 560 does not have a region overlapping with the conductor 542a or the conductor 542b. Thus, parasitic capacitance between the conductor 560 and each of the conductor 542a and the conductor 542b can be reduced. As a result, the transistor 500 can have increased switching speed and excellent frequency characteristics.

The conductor 560 sometimes functions as a first gate (also referred to as top gate) electrode. The conductor 503 sometimes functions as a second gate (also referred to as bottom gate) electrode. In that case, by changing a potential applied to the conductor 503 not in synchronization with but independently of a voltage applied to the conductor 560, the threshold voltage of the transistor 500 can be controlled. In particular, when a negative potential is applied to the conductor 503, the threshold voltage of the transistor 500 can be made higher than 0 V, and the off-state current can be reduced. Thus, a drain current at the time when a potential applied to the conductor 560 is 0 V can be made lower in the case where a negative potential is applied to the conductor 503 than in the case where a negative potential is not applied to the conductor 503.

The conductor 503 is positioned to be overlapped by the oxide 530 and the conductor 560. Accordingly, when a potential is applied to the conductor 560 and the conductor 503, an electric field generated from the conductor 560 and an electric field generated from the conductor 503 are connected, thereby covering the channel formation region in the oxide 530.

In this specification and the like, a transistor structure where a channel formation region is electrically surrounded by an electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor has the S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor has the S-channel structure, the GAA structure, or the LGAA structure, the channel formation region that is formed at the interface between the oxide 530 and a gate insulator or at the vicinity of the interface can be the entire bulk of the oxide 530. Accordingly, the density of current flowing through the transistor can be improved, which can be expected to increase the on-state current or the field-effect mobility of the transistor.

The conductor 503 has a structure similar to that of the conductor 518; a conductor 503a is formed in contact with an inner wall of an opening in the insulator 514 and the insulator 516, and a conductor 503b is formed over the conductor 503a so as to be embedded in the opening. Although the conductor 503a and the conductor 503b are stacked in the transistor 500, the present invention is not limited thereto. For example, the conductor 503 may have a single-layer structure or a stacked-layer structure of three or more layers.

Here, for the conductor 503a, it is preferable to use a conductive material that has a function of inhibiting diffusion of impurities such as a hydrogen atom, a hydrogen molecule, a water molecule, and a copper atom (a conductive material through which the impurities are less likely to pass). Alternatively, it is preferable to use a conductive material that has a function of inhibiting diffusion of oxygen (e.g., at least one of an oxygen atom, an oxygen molecule, and the like) (a conductive material through which the above oxygen is less likely to pass). Note that in this specification, the function of inhibiting diffusion of impurities or oxygen means a function of inhibiting diffusion of any one or all of the above impurities and the above oxygen.

For example, when the conductor 503a has a function of inhibiting diffusion of oxygen, a reduction in conductivity of the conductor 503b due to oxidation can be inhibited.

In the case where the conductor 503 also functions as a wiring, the conductor 503b is preferably formed using a conductive material with high conductivity that includes tungsten, copper, or aluminum as its main component. Although the conductor 503 is illustrated to have a stacked layer of the conductor 503a and the conductor 503b in this embodiment, the conductor 503 may have a single-layer structure.

The insulator 520, the insulator 522, and the insulator 524 have a function of a second gate insulating film.

Here, an insulator including oxygen more than that in the stoichiometric composition is preferably used as the insulator 524 in contact with the oxide 530. Such oxygen is easily released from the film by heating. In this specification and the like, oxygen released by heating is sometimes referred to as excess oxygen. That is, a region including excess oxygen (also referred to as an “excess-oxygen region”) is preferably formed in the insulator 524. When such an insulator including excess oxygen is provided in contact with the oxide 530, oxygen vacancies (V_{O}) in the oxide 530 can be reduced and the reliability of the transistor 500 can be increased. Note that when hydrogen enters the oxygen vacancies in the oxide 530, such defects (hereinafter referred to as V_{O}H in some cases) serve as donors and generate electrons serving as carriers in some cases. In other cases, bonding of part of hydrogen to oxygen bonded to a metal atom generates electrons serving as carriers. Thus, a transistor including an oxide semiconductor that includes a large amount of hydrogen is likely to have normally-on characteristics. Moreover, hydrogen in an oxide semiconductor is easily transferred by stress such as heat or an electric field; thus, the reliability of the transistor might be reduced when the oxide semiconductor includes a large amount of hydrogen. In one embodiment of the present invention, V_{O}H in the oxide 530 is preferably reduced as much as possible so that the oxide 530 becomes a highly purified intrinsic or substantially highly purified intrinsic oxide. In order to obtain such an oxide semiconductor with sufficiently reduced V_{O}H, it is important to remove impurities such as moisture and hydrogen in the oxide semiconductor (this treatment is also referred to as “dehydration” or “dehydrogenation treatment”) and supply oxygen to the oxide semiconductor to fill oxygen vacancies (this treatment is also referred to as “oxygen adding treatment”). When an oxide semiconductor with sufficiently reduced impurities such as V_{O}H is used for a channel formation region of a transistor, the transistor can have stable electrical characteristics.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm 3 , further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably higher than or equal to 100° C. and lower than or equal to 700° C., or higher than or equal to 100° C. and lower than or equal to 400° C.

Any one or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when reaction in which a bond of V_{O}H is cut occurs, i.e., reaction of “V_{O}H→V_{O}+H” occurs. Part of hydrogen generated at this time is bonded to oxygen and is removed as H₂O from the oxide 530 or an insulator in the vicinity of the oxide 530 in some cases. Some hydrogen may be gettered into the conductors 542a and 542b in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The microwave treatment is performed under a pressure of 133 Pa or higher, preferably 200 Pa or higher, further preferably 400 Pa or higher. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In the fabrication process of the transistor 500, the heat treatment is preferably performed with the surface of the oxide 530 exposed. For example, the heat treatment is performed at a temperature higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 530 to reduce oxygen vacancies (V_{O}). Alternatively, the heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at higher than or equal to 10 ppm, higher than or equal to 1%, or higher than or equal to 10% in order to compensate for released oxygen. Alternatively, the heat treatment may be performed in such a manner that heat treatment is performed in an atmosphere containing an oxidizing gas at higher than or equal to 10 ppm, higher than or equal to 1%, or higher than or equal to 10%, and then another heat treatment is successively performed in a nitrogen gas or inert gas atmosphere.

Note that oxygen adding treatment performed on the oxide 530 can promote reaction in which oxygen vacancies in the oxide 530 are filled with supplied oxygen, i.e., reaction of “V_{O}+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of V_{O}H.

In the case where the insulator 524 includes an excess-oxygen region, the insulator 522 preferably has a function of inhibiting diffusion of oxygen (e.g., oxygen atoms and oxygen molecules) (it is preferable that oxygen be less likely to pass through the insulator 522).

The insulator 522 preferably has a function of inhibiting diffusion of oxygen, impurities, or the like, in which case diffusion of oxygen included in the oxide 530 to the insulator 520 side is prevented. Furthermore, the conductor 503 can be inhibited from reacting with oxygen included in the insulator 524, the oxide 530, or the like.

The insulator 522 preferably has a single-layer structure or a stacked-layer structure using an insulator including what is called a high-k material such as aluminum oxide, hafnium oxide, an oxide including aluminum and hafnium (hafnium aluminate), tantalum oxide, zirconium oxide, lead zirconate titanate (PZT), strontium titanate (SrTiO₃), or (Ba,Sr)TiO₃ (BST), for example. As miniaturization and high integration of transistors progress, a problem such as off-state current might arise because of a thinner gate insulating film. When a high-k material is used for an insulator functioning as the gate insulating film, a gate potential during transistor operation can be reduced while the physical thickness is maintained.

It is particularly preferable to use an insulator including an oxide of one or both of aluminum and hafnium, which is an insulating material having a function of inhibiting diffusion of impurities, oxygen, and the like (an insulating material through which the above oxygen is less likely to pass). Aluminum oxide, hafnium oxide, an oxide including aluminum and hafnium (hafnium aluminate), or the like is preferably used for the insulator including an oxide of one or both of aluminum and hafnium. The insulator 522 formed of such a material functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to the insulator, for example. Alternatively, the insulator may be subjected to nitriding treatment. Silicon oxide, silicon oxynitride, or silicon nitride may be stacked over the insulator.

It is preferable that the insulator 520 be thermally stable. For example, silicon oxide and silicon oxynitride are preferred because of their thermal stability. Furthermore, a combination of an insulator that is a high-k material and silicon oxide or silicon oxynitride enables the insulator 520 to have a stacked-layer structure that has thermal stability and high relative permittivity.

Note that the transistor 500 in FIG. 13A and FIG. 13B includes the insulator 520, the insulator 522, and the insulator 524 as the second gate insulating film having a three-layer structure; however, the second gate insulating film may have a single-layer structure, a two-layer structure, or a stacked-layer structure of four or more layers. In such a case, the stacked layers are not necessarily formed of the same material and may be formed of different materials.

In the transistor 500, a metal oxide functioning as an oxide semiconductor is used as the oxide 530 including the channel formation region.

The metal oxide functioning as an oxide semiconductor may be formed by a sputtering method or an ALD (Atomic Layer Deposition) method. Note that the metal oxide functioning as an oxide semiconductor will be described in detail in another embodiment.

The metal oxide functioning as the channel formation region in the oxide 530 has a band gap of preferably 2 eV or more, further preferably 2.5 eV or more. The use of a metal oxide having such a wide band gap can reduce the off-state current of the transistor.

When the oxide 530 includes the oxide 530a under the oxide 530b, it is possible to inhibit diffusion of impurities into the oxide 530b from the components formed below the oxide 530a.

Note that the oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a junction portion of the oxide 530a and the oxide 530b. In other words, the energy level of the conduction band minimum at the junction portion of the oxide 530a and the oxide 530b continuously changes or is continuously connected. To change the energy level gradually, the density of defect states in a mixed layer formed at the interface between the oxide 530a and the oxide 530b is preferably made low.

Specifically, when the oxide 530a and the oxide 530b include a common element (as a main component) in addition to oxygen, a mixed layer with a low density of defect states can be formed. For example, in the case where the oxide 530b is an In—Ga−Zn oxide, an In—Ga—Zn oxide, a Ga—Zn oxide, gallium oxide, or the like is preferably used for the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have high on-state current.

The conductor 542a and the conductor 542b functioning as the source electrode and the drain electrode are provided over the oxide 530b. For the conductor 542a and conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including any of the above metal elements as its component; an alloy including a combination of the above metal elements; or the like. For example, it is preferable to use tantalum nitride, titanium nitride, tungsten, a nitride including titanium and aluminum, a nitride including tantalum and aluminum, ruthenium oxide, ruthenium nitride, an oxide including strontium and ruthenium, an oxide including lanthanum and nickel, or the like. Tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are oxidation-resistant conductive materials or materials that retain their conductivity even after absorbing oxygen. Furthermore, a metal nitride film of tantalum nitride or the like is preferable because it has a barrier property against hydrogen or oxygen.

Although the conductor 542a and the conductor 542b have a single-layer structure in FIG. 13A, they may have a stacked-layer structure of two or more layers. For example, it is preferable to stack a tantalum nitride film and a tungsten film. Alternatively, a titanium film and an aluminum film may be stacked. Other examples include a two-layer structure where an aluminum film is stacked over a tungsten film, a two-layer structure where a copper film is stacked over a copper-magnesium-aluminum alloy film, a two-layer structure where a copper film is stacked over a titanium film, and a two-layer structure where a copper film is stacked over a tungsten film.

Other examples include a three-layer structure where a titanium film or a titanium nitride film is formed, an aluminum film or a copper film is stacked over the titanium film or the titanium nitride film, and a titanium film or a titanium nitride film is formed over the aluminum film or the copper film; and a three-layer structure where a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material including indium oxide, tin oxide, or zinc oxide may be used.

As illustrated in FIG. 13A, a region 543a and a region 543b are sometimes formed as low-resistance regions at and near the interface between the oxide 530 and the conductor 542a (the conductor 542b). In that case, the region 543a functions as one of a source region and a drain region, and the region 543b functions as the other of the source region and the drain region. The channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that includes the metal included in the conductor 542a (the conductor 542b) and the component of the oxide 530 is sometimes formed in the region 543a (the region 543b). In such a case, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. Here, the insulator 544 may be provided to cover a side surface of the oxide 530 and to be in contact with the insulator 524.

A metal oxide including one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use, as the insulator 544, an insulator including an oxide of one or both of aluminum and hafnium, such as aluminum oxide, hafnium oxide, or an oxide including aluminum and hafnium (hafnium aluminate). In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen. Design is appropriately set in consideration of required transistor characteristics.

The insulator 544 can inhibit impurities such as water and hydrogen included in the insulator 580 from diffusing into the oxide 530b. Moreover, the oxidation of the conductors 542a and 542b due to excess oxygen included in the insulator 580 can be inhibited.

The insulator 545 functions as a first gate insulating film. Like the insulator 524 described above, the insulator 545 is preferably formed using an insulator that includes excess oxygen and releases oxygen by heating.

Specifically, it is possible to use any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide each including excess oxygen. In particular, silicon oxide and silicon oxynitride, which have thermal stability, are preferable.

When an insulator including excess oxygen is provided as the insulator 545, oxygen can be effectively supplied from the insulator 545 to the channel formation region of the oxide 530b. Furthermore, as in the insulator 524, the concentration of impurities such as water or hydrogen in the insulator 545 is preferably reduced. The thickness of the insulator 545 is preferably greater than or equal to 1 nm and less than or equal to 20 nm.

Furthermore, to efficiently supply excess oxygen included in the insulator 545 to the oxide 530, a metal oxide may be provided between the insulator 545 and the conductor 560. The metal oxide preferably inhibits diffusion of oxygen from the insulator 545 to the conductor 560. Providing the metal oxide that inhibits diffusion of oxygen inhibits diffusion of excess oxygen from the insulator 545 to the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as off-state current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have high relative permittivity.

Although the conductor 560 functioning as the first gate electrode has a two-layer structure in FIG. 13A and FIG. 13B, the conductor 560 may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, the conductivity of the conductor 560b can be inhibited from being lowered because of oxidation due to oxygen included in the insulator 545. As a conductive material having a function of inhibiting diffusion of oxygen, for example, tantalum, tantalum nitride, ruthenium, ruthenium oxide, or the like is preferably used. Alternatively, the conductor 560a can be formed using an oxide semiconductor that can be used for the oxide 530. In that case, when the conductor 560b is deposited by a sputtering method, the conductor 560a can have a reduced electrical resistance and become a conductor. Such a conductor can be referred to as an OC (Oxide Conductor) electrode.

The conductor 560b is preferably formed using a conductive material including tungsten, copper, or aluminum as its main component. The conductor 560b also functions as a wiring and thus is preferably formed using a conductor having high conductivity. For example, a conductive material including tungsten, copper, or aluminum as its main component can be used. The conductor 560b may have a stacked-layer structure, for example, a stacked-layer structure of titanium or titanium nitride and the above conductive material.

The insulator 580 is provided over the conductor 542a and the conductor 542b with the insulator 544 therebetween. The insulator 580 preferably includes an excess-oxygen region. For example, the insulator 580 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, resin, or the like. In particular, silicon oxide and silicon oxynitride, which have thermal stability, are preferable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with the top surface of the insulator 580, the top surface of the conductor 560, and the top surface of the insulator 545. When the insulator 574 is deposited by a sputtering method, excess-oxygen regions can be provided in the insulator 545 and the insulator 580. Accordingly, oxygen can be supplied from the excess-oxygen regions to the oxide 530.

For example, a metal oxide including one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

An insulator 581 functioning as an interlayer film is preferably provided over the insulator 574. As in the insulator 524 or the like, the concentration of impurities such as water or hydrogen in the insulator 581 is preferably reduced.

A conductor 540a and a conductor 540b are positioned in openings formed in the insulator 581, the insulator 574, the insulator 580, and the insulator 544. The conductor 540a and the conductor 540b are provided to face each other with the conductor 560 therebetween. The conductor 540a and the conductor 540b have a structure similar to that of a conductor 546 and a conductor 548 described later.

An insulator 582 is provided over the insulator 581. A substance having a barrier property against oxygen, hydrogen, or the like is preferably used for the insulator 582. Thus, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents passage of both oxygen and impurities such as hydrogen and moisture that cause a change in electrical characteristics of the transistor. Accordingly, the use of aluminum oxide can prevent entry of impurities such as hydrogen and moisture into the transistor 500 during and after a fabrication process of the transistor. In addition, release of oxygen from the oxide included in the transistor 500 can be inhibited. Thus, aluminum oxide is suitably used for a protective film of the transistor 500.

An insulator 586 is provided over the insulator 582. For the insulator 586, a material similar to that for the insulator 320 can be used. In the case where a material with relatively low permittivity is used for these insulators, the parasitic capacitance between wirings can be reduced. For example, a silicon oxide film, a silicon oxynitride film, or the like can be used for the insulator 586.

The conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be formed using a material similar to that for the conductor 328 and the conductor 330.

After the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, formation of an opening reaching the insulator 522 or the insulator 514 and formation of the insulator having a high barrier property to be in contact with the insulator 522 or the insulator 514 are suitable because these formation steps can also serve as some of the fabrication steps of the transistor 500. Note that for the insulator having a high barrier property against hydrogen or water, a material similar to that for the insulator 522 or the insulator 514 can be used, for example.

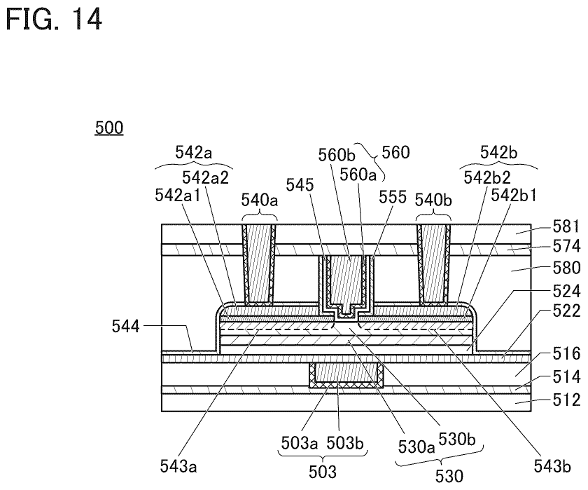

Note that the transistor that can be used in the present invention is not limited to the transistor 500 illustrated in FIG. 13A and FIG. 13B. For example, the transistor 500 having a structure illustrated in FIG. 14 may be used. The transistor 500 illustrated in FIG. 14 is different from the transistor illustrated in FIG. 13A and FIG. 13B in that an insulator 555 is used and that the conductor 542a (a conductor 542a1 and a conductor 542a2) and the conductor 542b (a conductor 542b1 and a conductor 542b2) each have a stacked-layer structure.

The conductor 542a has a stacked-layer structure of the conductor 542a1 and the conductor 542a2 over the conductor 542a1, and the conductor 542b has a stacked-layer structure of the conductor 542b1 and the conductor 542b2 over the conductor 542b1. The conductor 542a1 and the conductor 542b1 in contact with the oxide 530b are preferably conductors that are less likely to be oxidized, such as a metal nitride. Thus, excessive oxidation of the conductor 542a and the conductor 542b due to oxygen included in the oxide 530b can be prevented. Moreover, the conductor 542a2 and the conductor 542b2 are preferably conductors having higher conductivity than the conductor 542a1 and the conductor 542b1, such as a metal layer. Thus, the conductor 542a and the conductor 542b can function as wirings or electrodes having high conductivity. In this manner, it is possible to provide a semiconductor device in which the conductor 542a and the conductor 542b that function as wirings or electrodes are provided in contact with the top surface of the oxide 530 functioning as an active layer.

As the conductors 542a1 and 542b1, a metal nitride is preferably used; for example, a nitride including tantalum, a nitride including titanium, a nitride including molybdenum, a nitride including tungsten, a nitride including tantalum and aluminum, or a nitride including titanium and aluminum is preferably used. In one embodiment of the present invention, a nitride including tantalum is particularly preferable. As another example, ruthenium, ruthenium oxide, ruthenium nitride, an oxide including strontium and ruthenium, or an oxide including lanthanum and nickel may be used. These materials are preferable because they are each a conductive material that is less likely to be oxidized or a material that maintains the conductivity even after absorbing oxygen.

The conductor 542a2 and the conductor 542b2 preferably have higher conductivity than the conductor 542a1 and the conductor 542b1. For example, the thicknesses of the conductor 542a2 and the conductor 542b2 are preferably larger than the thicknesses of the conductor 542a1 and the conductor 542b1. For the conductor 542a2 and the conductor 542b2, a conductor that can be used for the conductor 560b can be used. The above structure can reduce the resistance of the conductor 542a2 and the conductor 542b2.

For example, tantalum nitride or titanium nitride can be used for the conductor 542a1 and the conductor 542b1, and tungsten can be used for the conductor 542a2 and the conductor 542b2.

As illustrated in FIG. 14, in a cross-sectional view of the transistor 500 in the channel length direction, the distance between the conductor 542a1 and the conductor 542b1 is smaller than the distance between the conductor 542a2 and the conductor 542b2. With such a structure, the distance between the source and the drain can be shortened, and the channel length can be accordingly shortened. Thus, the frequency characteristics of the transistor 500 can be improved. In this manner, miniaturization of the semiconductor device enables the semiconductor device to have a higher operating speed.

The insulator 555 is preferably an insulator that is less likely to be oxidized, such as a nitride. The insulator 555 is formed in contact with a side surface of the conductor 542a2 and a side surface of the conductor 542b2 and has a function of protecting the conductor 542a2 and the conductor 542b2. The insulator 555 is exposed to an oxidized atmosphere, and thus is preferably an inorganic insulator that is less likely to be oxidized. Since the insulator 555 is in contact with the conductor 542a2 and the conductor 542b2, the insulator 555 is preferably an inorganic insulator that is less likely to oxidize the conductors 542a2 and 542b2. Therefore, for the insulator 555, an insulating material having a barrier property against oxygen is preferably used. For example, silicon nitride can be used for the insulator 555.

The transistor 500 illustrated in FIG. 14 is formed in the following manner: an opening is formed in the insulator 580 and the insulator 544, the insulator 555 is formed in contact with a sidewall of the opening, and then the conductor 542a1 and the conductor 542b1 are separated using a mask. Here, the opening overlaps with a region between the conductor 542a2 and the conductor 542b2. The conductor 542a1 and the conductor 542b1 are formed to partly extend in the opening. Thus, in the opening, the insulator 555 is in contact with the top surface of the conductors 542a1, the top surface of the conductor 542b1, the side surface of the conductor 542a2, and the side surface of the conductor 542b2. The insulator 545 is in contact with the top surface of the oxide 530 in a region between the conductor 542a1 and the conductor 542b1.

Heat treatment in an atmosphere containing oxygen is preferably performed after the separation of the conductor into the conductor 542a1 and the conductor 542b1 but before the deposition of the insulator 545. Thus, oxygen can be supplied to the oxide 530a and the oxide 530b to reduce oxygen vacancies. Furthermore, since the insulator 555 is formed in contact with the side surface of the conductor 542a2 and the side surface of the conductor 542b2, excessive oxidation of the conductor 542a2 and the conductor 542b2 can be prevented. Accordingly, the transistor can have favorable electrical characteristics and higher reliability. In addition, variations in electrical characteristics of transistors formed over the same substrate can be reduced.

In the transistor 500, the insulator 524 may be formed into an island shape, as illustrated in FIG. 14. Here, the insulator 524 may be formed such that its side end portion is substantially aligned with a side end portion of the oxide 530.

In the transistor 500, the insulator 522 may be in contact with the insulator 516 and the conductor 503, as illustrated in FIG. 14. In other words, the insulator 520 illustrated in FIG. 13A and FIG. 13B may be omitted.

Next, the capacitor 600 is provided above the transistor 500. The capacitor 600 includes a conductor 610, a conductor 620, and an insulator 630.

A conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, it is possible to use a metal film including an element selected from molybdenum, titanium, tantalum, tungsten, aluminum, copper, chromium, neodymium, and scandium; a metal nitride film including the above element as its component (a tantalum nitride film, a titanium nitride film, a molybdenum nitride film, or a tungsten nitride film); or the like. Alternatively, it is possible to employ a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the conductor 612 and the conductor 610 each have a single-layer structure in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In the case where the conductor 620 is formed at the same time as another component such as a conductor, copper (Cu), aluminum (Al), or the like, which is a low-resistance metal material, is used.

An insulator 640 is provided over the conductor 620 and the insulator 630. The insulator 640 can be formed using a material similar to that for the insulator 320. The insulator 640 may function as a planarization film that covers an uneven shape thereunder

With the use of this structure, a semiconductor device using a transistor including an oxide semiconductor can be miniaturized or highly integrated.

As a substrate that can be used for the semiconductor device of one embodiment of the present invention, a glass substrate, a quartz substrate, a sapphire substrate, a ceramic substrate, a metal substrate (e.g., a stainless steel substrate, a substrate including stainless steel foil, a tungsten substrate, a substrate including tungsten foil, or the like), a semiconductor substrate (e.g., a single crystal semiconductor substrate, a polycrystalline semiconductor substrate, a compound semiconductor substrate, or the like), an SOI (silicon on Insulator) substrate, or the like can be used. Alternatively, a plastic substrate having heat resistance to the processing temperature in this embodiment may be used. Examples of the glass substrate include barium borosilicate glass, aluminosilicate glass, aluminoborosilicate glass, and soda lime glass. Alternatively, crystallized glass or the like can be used.

Alternatively, a flexible substrate; an attachment film; paper or a base film including a fibrous material; or the like can be used as the substrate. As examples of the flexible substrate, the attachment film, the base film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Other examples include polyamide, polyimide, an aramid resin, an epoxy resin, an inorganic evaporated film, and paper. In particular, the use of a semiconductor substrate, a single crystal substrate, an SOI substrate, or the like for the manufacture of transistors enables the manufacture of small-sized transistors with a small variation in characteristics, size, shape, or the like and high current capability. A circuit using such transistors achieves lower power consumption or higher integration.

Alternatively, a flexible substrate may be used as the substrate, and a transistor, a resistor, a capacitor, and/or the like may be formed directly on the flexible substrate. Alternatively, a separation layer may be provided between the substrate and the transistor, the resistor, the capacitor, and/or the like. After part or the whole of a semiconductor device is completed over the separation layer, the separation layer can be used for separation from the substrate and transfer to another substrate. In such a case, the transistor, the resistor, the capacitor, and/or the like can be transferred to a substrate having low heat resistance, a flexible substrate, or the like. Note that as the separation layer, a stacked-layer structure of a tungsten film and a silicon oxide film that are inorganic films, a structure in which an organic resin film of polyimide or the like is formed over a substrate, a silicon film including hydrogen, or the like can be used, for example.

That is, a semiconductor device may be formed over one substrate and then transferred to another substrate. Examples of a substrate to which a semiconductor device is transferred include, in addition to the above substrates over which transistors can be formed, a paper substrate, a cellophane substrate, an aramid film substrate, a polyimide film substrate, a stone substrate, a wood substrate, a cloth substrate (including a natural fiber (silk, cotton, or hemp), a synthetic fiber (nylon, polyurethane, or polyester), a regenerated fiber (acetate, cupro, rayon, or regenerated polyester), or the like), a leather substrate, and a rubber substrate. With the use of these substrates, the manufacture of a flexible semiconductor device, the manufacture of a robust semiconductor device, provision of high heat resistance, a reduction in weight, or a reduction in thickness can be achieved.

Providing a semiconductor device over a flexible substrate can inhibit an increase in weight and makes the semiconductor device less likely to be damaged.

Note that the transistor 550 illustrated in FIG. 12 is just an example and is not limited to the structure illustrated therein, and an appropriate transistor can be used in accordance with a circuit structure, a driving method, or the like. For example, when the semiconductor device is a single-polarity circuit that is composed of only OS transistors (which means transistors having the same polarity, e.g., only n-channel transistors), the transistor 550 has a structure similar to that of the transistor 500.

The configuration, structure, method, and the like described in this embodiment can be used in combination as appropriate with the configurations, structures, methods, and the like described in the other embodiments, an example, and the like.

### Embodiment 3

In this embodiment, a cross-sectional structure example of an element layer including stacked OS transistors that can be used in a memory device, a data retention circuit, a memory circuit, and the like is described. In this embodiment, an example of a schematic cross-sectional view applicable to a circuit structure of a DOSRAM or a NOSRAM is described.

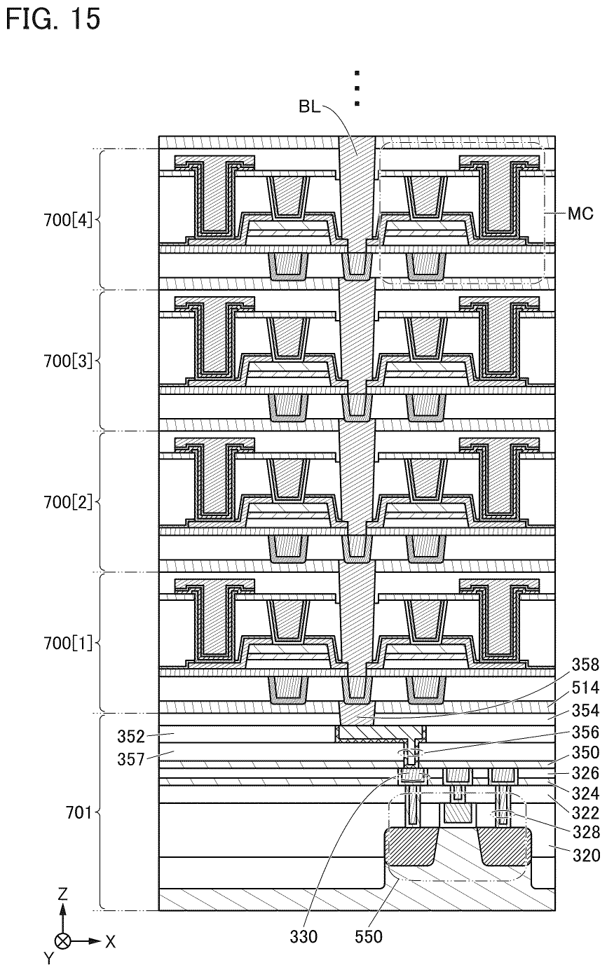

FIG. 15 illustrates a cross-sectional structure example of the case of using a DOSRAM circuit structure. In the example illustrated in FIG. 15, an element layer 700[1] to an element layer 700[4] are stacked over an element layer 701.

FIG. 15 also illustrates the transistor 550 included in the element layer 701 as an example. As the transistor 550, the transistor 550 described in the above embodiment can be used.

Note that the transistor 550 illustrated in FIG. 15 is an example and is not limited to the structure illustrated therein; an appropriate transistor can be used in accordance with a circuit structure or a driving method.

A wiring layer provided with an interlayer film, a wiring, a plug, and the like may be provided between the element layer 701 and the element layer 700 or between a k-th element layer 700 and a (k+1)-th element layer 700. Note that in this embodiment and the like, the k-th element layer 700 is denoted as an element layer 700[k] and the (k+1)-th element layer 700 is denoted as an element layer 700[k+1] in some cases. Here, k is an integer greater than or equal to 1 and less than or equal to N. In addition, in this embodiment and the like, the solutions of “k+a (a is an integer greater than or equal to 1)” and “k-α” are each an integer greater than or equal to 1 and less than or equal to N.

A plurality of wiring layers can be provided in accordance with the design. Moreover, in this specification and the like, a wiring and a plug electrically connected to the wiring may be a single component. That is, part of a conductor functions as a wiring in some cases and part of a conductor functions as a plug in other cases.

For example, the insulator 320, the insulator 322, the insulator 324, and the insulator 326 are sequentially stacked and provided over the transistor 550 as interlayer films. The conductor 328 and the like are embedded in the insulator 320 and the insulator 322. The conductor 330 and the like are embedded in the insulator 324 and the insulator 326. Note that the conductor 328 and the conductor 330 each function as a contact plug or a wiring.

The insulator functioning as an interlayer film may function as a planarization film that covers an uneven shape thereunder. For example, the top surface of the insulator 320 may be planarized through planarization treatment using a CMP method or the like to increase the level of planarity.

A wiring layer may be provided over the insulator 326 and the conductor 330. For example, in FIG. 15, the insulator 350, an insulator 357, the insulator 352, and the insulator 354 are sequentially stacked and provided over the insulator 326 and the conductor 330. The conductor 356 is formed in the insulator 350, the insulator 357, and the insulator 352. The conductor 356 functions as a contact plug or a wiring.

The insulator 514 included in the element layer 700[1] is provided over the insulator 354. A conductor 358 is embedded in the insulator 514 and the insulator 354. The conductor 358 functions as a contact plug or a wiring. For example, a wiring BL and the transistor 550 are electrically connected to each other through the conductor 358, the conductor 356, the conductor 330, and the like.

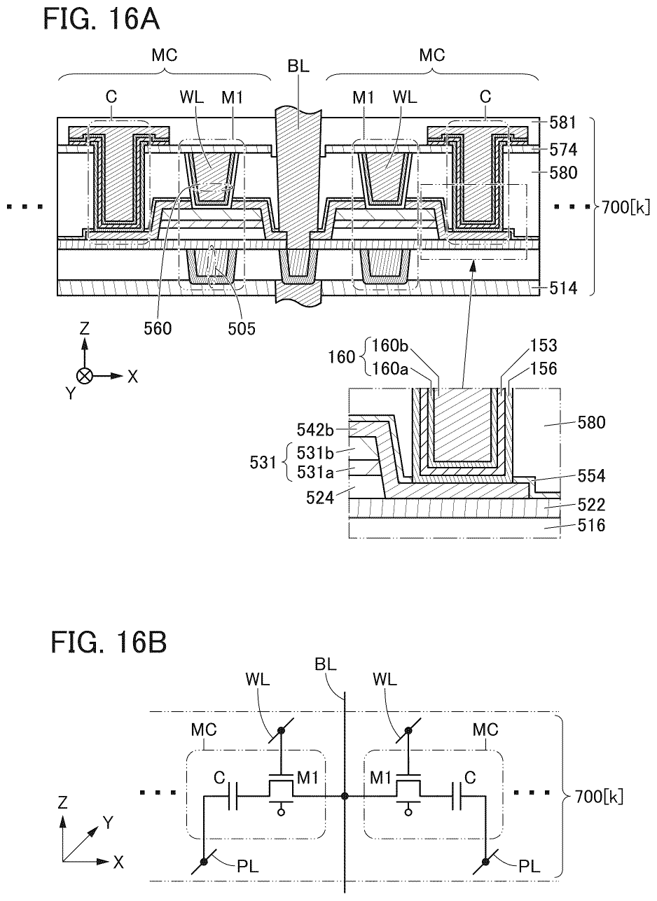

FIG. 16A illustrates a cross-sectional structure example of the element layer 700[k]. FIG. 16B is an equivalent circuit diagram of FIG. 16A. FIG. 16A illustrates an example where two memory cells MC are electrically connected to one wiring BL.

The memory cell MC illustrated in FIG. 15 and FIG. 16A includes the transistor M1 and the capacitor C. For example, the transistor 500 illustrated in the above embodiment can be used as the transistor M1.

Note that in this embodiment, a variation example of the transistor 500 is illustrated as the transistor M1. Specifically, the transistor M1 is different from the transistor 500 in that the conductor 542a and the conductor 542b extend beyond an edge of a metal oxide 531 (a metal oxide 531a and a metal oxide 531b).

The memory cell MC illustrated in FIG. 15 and FIG. 16A includes a conductor 156 that functions as one terminal of the capacitor C, an insulator 153 that functions as a dielectric, and a conductor 160 (a conductor 160a and a conductor 160b) that functions as the other terminal of the capacitor C. The conductor 156 is electrically connected to part of the conductor 542b. The conductor 160 is electrically connected to the wiring PL (not illustrated in FIG. 16A).

The capacitor C is formed in an opening portion that is provided by removal of part of the insulator 574, the insulator 580, and an insulator 554. Since the conductor 156, the insulator 580, and the insulator 554 are formed along a side surface of the opening portion, the conductor 156, the insulator 580, and the insulator 554 are preferably deposited by an ALD method, a CVD method, or the like.

A conductor that can be used for a conductor 505 or the conductor 560 is used for each of the conductor 156 and the conductor 160. For example, titanium nitride formed by an ALD method is used for the conductor 156. Furthermore, titanium nitride formed by an ALD method is used for the conductor 160a, and tungsten formed by a CVD method is used for the conductor 160b. Note that in the case where the adhesion of tungsten to the insulator 153 is sufficiently high, a single-layer film of tungsten formed by a CVD method may be used for the conductor 160.

An insulator of a high permittivity (high-k) material (a material with high relative permittivity) is preferably used for the insulator 153. As the insulator of a high permittivity material, an oxide, an oxynitride, a nitride oxide, or a nitride containing one or more kinds of metal element selected from aluminum, hafnium, zirconium, gallium, and the like can be used, for example. In addition, the oxide, the oxynitride, the nitride oxide, or the nitride may contain silicon. Furthermore, insulating layers each formed of the above material can be stacked to be used. The insulator 153 can employ, for example, a three-layer stacked structure of zirconium oxide, aluminum oxide, and zirconium oxide. Note that the three-layer stacked structure may be referred to as ZrOₓₐ\AlO_{xb}\ZrO_{xc} (ZAZ). Note that xa, xb, and xc mentioned above each have an arbitrary unit.

As the insulator of a high permittivity material, it is possible to use, for example, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, or an oxynitride containing hafnium and zirconium. Using such a high permittivity material allows the insulator 153 to be thick enough to inhibit the off-state current and can ensure sufficient capacitance of the capacitor C.

In addition, it is preferable to use stacked insulating layers each formed of the above materials. It is preferable to use a stacked structure using a high permittivity material and a material having higher dielectric strength than the high permittivity material. An insulating film in which zirconium oxide, aluminum oxide, and zirconium oxide are stacked in this order can be used for the insulator 153, for example. Alternatively, an insulating film in which zirconium oxide, aluminum oxide, zirconium oxide, and aluminum oxide are stacked in this order can be used, for example. Alternatively, an insulating film in which hafnium zirconium oxide, aluminum oxide, hafnium zirconium oxide, and aluminum oxide are stacked in this order can be used, for example. The use of stacked insulators with comparatively high dielectric strength, such as aluminum oxide, can improve the dielectric strength and can inhibit electrostatic breakdown of the capacitor C.

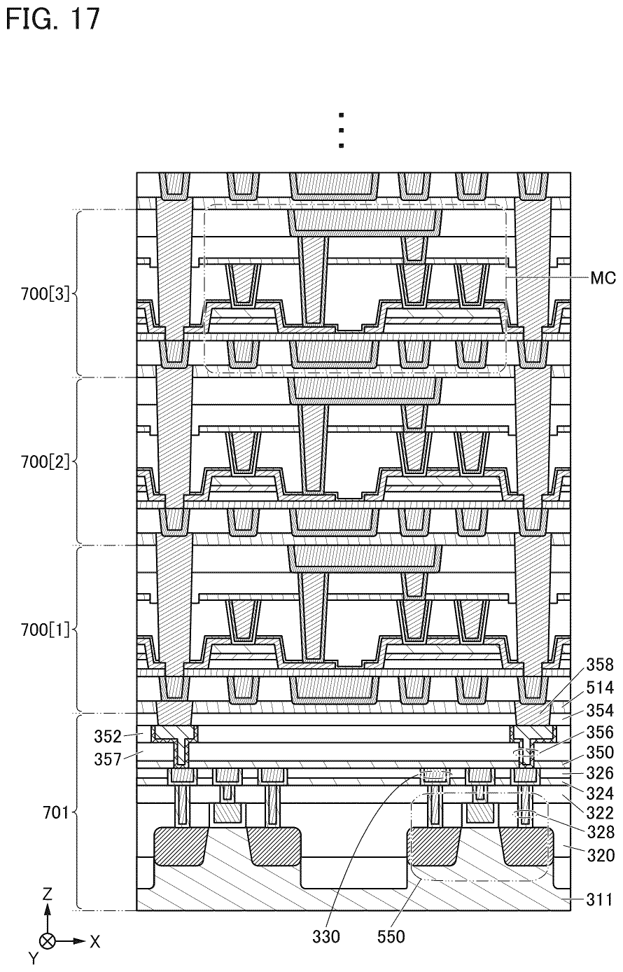

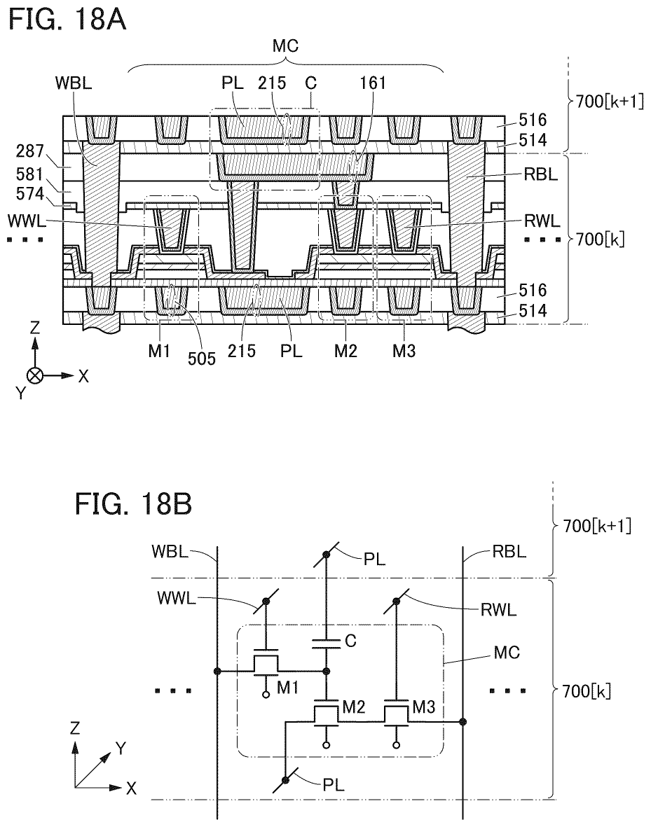

FIG. 17 illustrates a cross-sectional structure example of the case of using a NOSRAM memory cell circuit structure. FIG. 17 is also a variation example of FIG. 15. FIG. 18A illustrates a cross-sectional structure example of the element layer 700[k]. FIG. 18B is an equivalent circuit diagram of FIG. 18A.

The memory cell MC illustrated in FIG. 17 and FIG. 18A includes the transistor M1, a transistor M2, and a transistor M3 over the insulator 514. A conductor 215 is provided over the insulator 514. The conductor 215 and the conductor 505 can be concurrently formed using the same material in the same step.

The transistor M2 and the transistor M3 illustrated in FIG. 17 and FIG. 18A share one island-shaped metal oxide 531. In other words, part of the one island-shaped metal oxide 531 functions as a channel formation region of the transistor M2, and another part thereof functions as a channel formation region of the transistor M3. Furthermore, a source of the transistor M2 and a drain of the transistor M3 are shared, or a drain of the transistor M2 and a source of the transistor M3 are shared. Thus, the area occupied by the transistor M2 and the transistor M3 is smaller than that of the case where the transistor M2 and the transistor M3 are independently provided.

In the memory cell MC illustrated in FIG. 17 and FIG. 18A, an insulator 287 is provided over the insulator 581, and a conductor 161 is embedded in the insulator 287. The insulator 514 of the element layer 700[k+1] is provided over the insulator 287 and the conductor 161.

In FIG. 17 and FIG. 18A, the conductor 215 of the element layer 700[k+1] functions as one terminal of the capacitor C, the insulator 514 of the element layer 700[k+1] functions as a dielectric of the capacitor C, and the conductor 161 functions as the other terminal of the capacitor C. The other of a source and a drain of the transistor M1 is electrically connected to the conductor 161 through a contact plug, and a gate of the transistor M2 is electrically connected to the conductor 161 through another contact plug.

This embodiment can be implemented in combination with the other embodiments described in this specification as appropriate.

### Embodiment 4

In this embodiment, a transistor whose channel formation region includes an oxide semiconductor (OS transistor) will be described. Note that in the description of the OS transistor, comparison with a transistor whose channel formation region includes silicon (also referred to as a Si transistor) will also be briefly described.

### OS Transistor

An oxide semiconductor having a low carrier concentration is preferably used for the OS transistor. For example, the carrier concentration in a channel formation region of an oxide semiconductor is lower than or equal to 1×10¹⁸ cm³, preferably lower than 1×10¹⁷ cm³, further preferably lower than 1×10¹⁶ cm³, still further preferably lower than 1×10¹³ cm³, yet still further preferably lower than 1×10¹⁰ cm³, and higher than or equal to 1×10⁹ cm³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, it is preferable that the impurity concentration in an adjacent film be also reduced. Examples of the impurity include hydrogen and nitrogen. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as V_{O}H) may be formed and may generate an electron serving as a carrier. When V_{O}H is formed in the channel formation region, the donor concentration in the channel formation region increases in some cases. As the donor concentration in the channel formation region increases, the threshold voltage might vary. Therefore, when the channel formation region in the oxide semiconductor includes oxygen vacancies, the transistor is likely to have normally-on characteristics (characteristics with which, even when no voltage is applied to a gate electrode, a channel exists and current flows through the transistor). Accordingly, impurities, oxygen vacancies, and V_{O}H are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In the Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, the OS transistor is a transistor where the short-channel effect does not appear or hardly appears.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), and an increase in leakage current. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor, and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to a short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, a difference in energy of the conduction band minimum between the channel formation region and the source region or the drain region might decrease to higher than or equal to 0.1 eV and lower than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source region and the drain region become n⁺-type regions.

The OS transistor with the above structure can have favorable electrical characteristics even when a semiconductor device is miniaturized or highly integrated. For example, the OS transistor can have favorable electrical characteristics even when a gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Thus, the OS transistor can be used as a transistor with a short channel length more suitably than the Si transistor. Note that the gate length refers to the length of a gate electrode in a direction in which carriers move inside a channel formation region during operation of a transistor, and corresponds to the width of a bottom surface of the gate electrode in a plan view of the transistor.

Miniaturization of the OS transistor can improve the high frequency characteristics of the transistor. Specifically, the cutoff frequency of the transistor can be increased. When the gate length of the OS transistor is within any of the above ranges, the cutoff frequency of the transistor can be greater than or equal to 50 GHz, preferably greater than or equal to 100 GHz, further preferably greater than or equal to 150 GHz at room temperature, for example.

As described above, the OS transistor has effects superior to those of the Si transistor, such as a low off-state current and capability of having a short channel length.

The configuration, structure, method, and the like described in this embodiment can be used in combination as appropriate with the configurations, structures, methods, and the like described in the other embodiments and the like.

### Embodiment 5

This embodiment will describe an electronic component, an electronic device, a large computer, space equipment, and a data center (also referred to as DC) that can use the semiconductor device described in the above embodiment. An electronic component, an electronic device, a large computer, space equipment, and a data center each using the semiconductor device of one embodiment of the present invention are effective in achieving high performance, e.g., reducing power consumption.

### Electronic Component

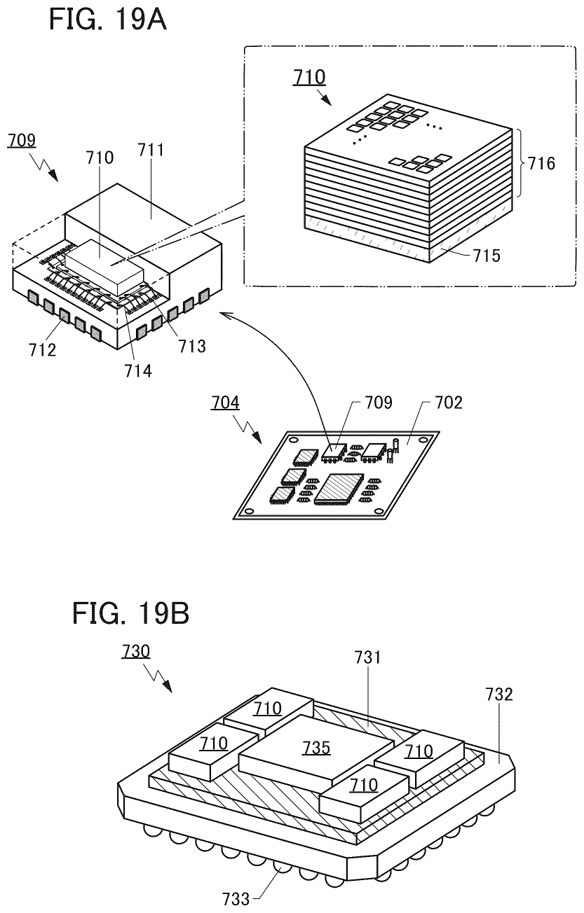

FIG. 19A is a perspective view of a substrate (a circuit board 704) on which an electronic component 709 is mounted. The electronic component 709 illustrated in FIG. 19A includes a semiconductor device 710 in a mold 711. Some components are omitted in FIG. 19A to show the inside of the electronic component 709. The electronic component 709 includes a land 712 outside the mold 711. The land 712 is electrically connected to an electrode pad 713, and the electrode pad 713 is electrically connected to the semiconductor device 710 through a wire 714. The electronic component 709 is mounted on a printed circuit board 702, for example. A plurality of such electronic components are combined and electrically connected to each other on the printed circuit board 702, which forms the circuit board 704.

The semiconductor device 710 includes a driver circuit layer 715 and an element layer 716. The element layer 716 has a structure in which a plurality of memory cell arrays are stacked. A stacked-layer structure of the driver circuit layer 715 and the element layer 716 can be a monolithic stacked-layer structure. In the monolithic stacked-layer structure, layers can be connected without using a through electrode technique such as a TSV (Through Silicon Via) and a bonding technique such as Cu-Cu direct bonding. The monolithic stacked-layer structure of the driver circuit layer 715 and the element layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as memory bandwidth).

It is preferable that the plurality of memory cell arrays included in the element layer 716 be formed using OS transistors and be monolithically stacked. The monolithic stacked-layer structure of a plurality of memory cell arrays can improve one or both of the bandwidth of the memory and the access latency of the memory. Note that a bandwidth refers to a data transfer volume per unit time, and access latency refers to time from access to start of data transmission. In the case where the element layer 716 is formed using Si transistors, it is difficult to obtain the monolithic stacked-layer structure as compared with the case where the element layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 19B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on the bottom portion of the package substrate 732. FIG. 19B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### Electronic Device

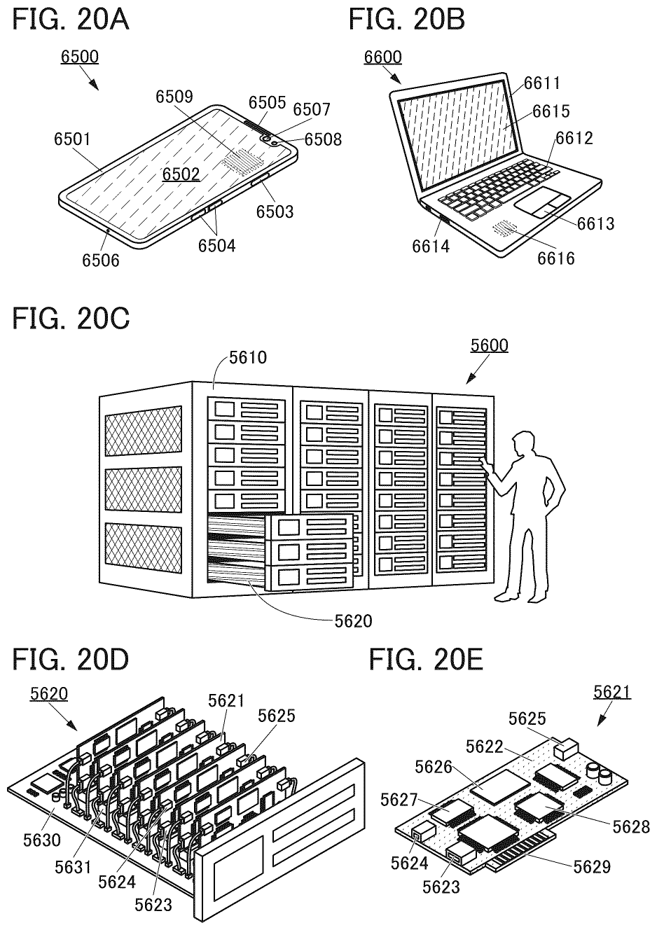

FIG. 20A is a perspective view of an electronic device 6500. The electronic device 6500 illustrated in FIG. 20A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The semiconductor device of one embodiment of the present invention can be used for the display portion 6502, the control device 6509, and the like.

An electronic device 6600 illustrated in FIG. 20B is an information terminal that can be used as a laptop personal computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The semiconductor device of one embodiment of the present invention can be used for the display portion 6615, the control device 6616, and the like. Note that the semiconductor device of one embodiment of the present invention is suitably used for the above-described control device 6509 and control device 6616, in which case power consumption can be reduced.

### Large Computer

FIG. 20C is a perspective view of a large computer 5600. In the large computer 5600 illustrated in FIG. 20C, a plurality of rack mount computers 5620 are stored in a rack 5610. Note that the large computer 5600 may be referred to as a supercomputer.

The computer 5620 can have a structure in a perspective view illustrated in FIG. 20D, for example. In FIG. 20D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 20E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 20E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device. As the semiconductor device 5628, the electronic component 709 can be used, for example.

The large computer 5600 can also function as a parallel computer. When the large computer 5600 is used as a parallel computer, large-scale computation necessary for artificial intelligence learning and inference can be performed, for example.

### Space Equipment

The semiconductor device of one embodiment of the present invention can be suitably used for space equipment such as equipment that processes and stores information.

The semiconductor device of one embodiment of the present invention can include an OS transistor. A change in electrical characteristics of the OS transistor due to exposure to radiation is small. That is, the OS transistor is highly resistant to radiation and thus can be suitably used in an environment where radiation can enter. For example, the OS transistor can be suitably used in outer space.

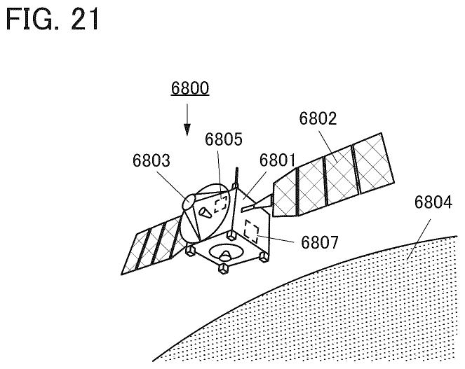

FIG. 21 illustrates an artificial satellite 6800 as an example of space equipment. The artificial satellite 6800 includes a body 6801, a solar panel 6802, an antenna 6803, a secondary battery 6805, and a control device 6807. Note that in FIG. 21, a planet 6804 in outer space is illustrated as an example. Note that outer space refers to, for example, space at an altitude greater than or equal to 100 km, and outer space in this specification may also include the thermosphere, mesosphere, and stratosphere.

Although not illustrated in FIG. 21, the secondary battery 6805 may be provided with a battery management system (also referred to as a BMS) or a battery control circuit. An OS transistor is suitably used in the battery management system or the battery control circuit because low power consumption and high reliability even in outer space are achieved.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a memory device, for example. Note that the semiconductor device of one embodiment of the present invention is suitably used for the control device 6807. A change in electrical characteristics due to exposure to radiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, the OS transistor has excellent effects of achieving wide memory bandwidth and being highly resistant to radiation as compared with the Si transistor.

### Data Center

The semiconductor device of one embodiment of the present invention can be suitably used for a storage system in a data center, for example. Long-term management of data, such as guarantee of data immutability, is required for the data center. The long-term management of data needs an increase in building size for, for example, setting a storage and a server for storing an enormous amount of data, ensuring stable power supply for data retention, and ensuring cooling equipment for data retention.

With the use of the semiconductor device of one embodiment of the present invention for the storage system used in the data center, electric power required for data retention can be reduced and a semiconductor device retaining data can be downsized. Thus, downsizing of the storage system, downsizing of the power supply for data retention, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

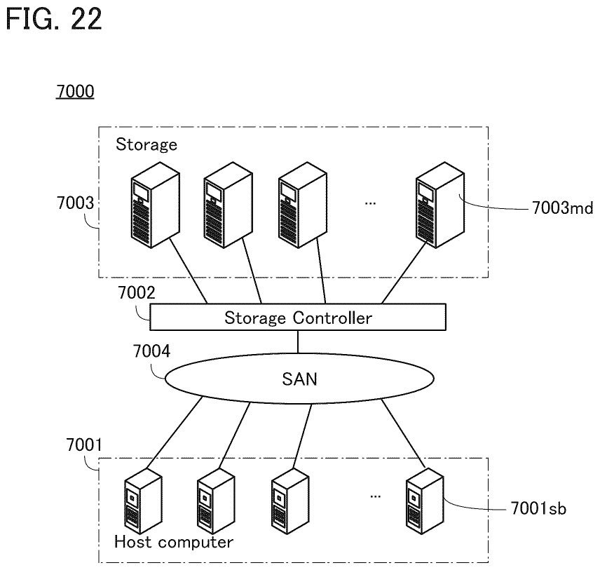

FIG. 22 illustrates a storage system that can be used in a data center. A storage system 7000 illustrated in FIG. 22 includes a plurality of servers 7001sb as a host 7001 (indicated as “Host computer” in the diagram). The storage system 7000 includes a plurality of memory devices 7003md as a storage 7003 (indicated as “Storage” in the diagram). In the illustrated example, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is considerably longer than the data access speed of a DRAM that can be used as a cache memory in the storage. In the storage system, in order to solve the problem of low access speed of the storage 7003, a cache memory is normally provided in the storage to shorten the time for data storage and output.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device of one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. The semiconductor device of one embodiment of the present invention can be effectively used as one of the global warming countermeasures because of its low power consumption.

The configuration, structure, method, and the like described in this embodiment can be used in combination as appropriate with the configurations, structures, methods, and the like described in the other embodiments and the like.

### Example 1

A semiconductor device including a CPU and an accelerator respectively corresponding to the arithmetic device 100 and the arithmetic device 200 described in Embodiment 1 was fabricated using a technique of stacking element layers (also referred to as an OS layer) including a transistor including an In—Ga—Zn—Oxide semiconductor having crystallinity (also referred to as an IGZO-FET) in a semiconductor layer. The fabricated semiconductor device includes a power supply circuit, a CPU memory for retaining data of the CPU, and the like as other components. The CPU memory corresponds to the memory device 300 described in Embodiment 1.

The fabricated semiconductor device was fabricated through a process in which two OS layers, which are element layers of IGZO-FETs fabricated with a 200-nm technology, were stacked over a Si CMOS circuit fabricated with a 130-nm technology.

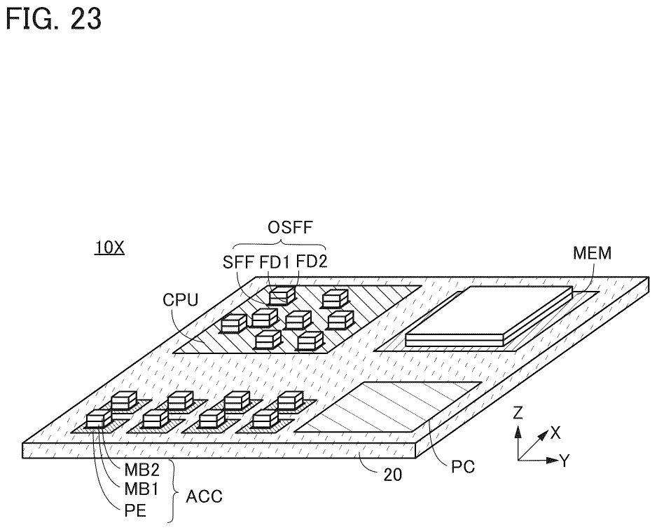

FIG. 23 is a schematic diagram illustrating an external view of a chip of a fabricated semiconductor device 10X. In FIG. 23, the OS layer is partly provided over the element layer 20 where the Si CMOS circuit is provided. In the CPU illustrated in FIG. 23, an OS flip-flop OSFF in which data retention circuits (hereinafter, backup memories) FD1 and FD2 are stacked over a scan flip-flop SFF provided in the element layer 20 is provided. In an accelerator ACC illustrated in FIG. 23, a plurality of blocks each including a product-sum operation processing element (hereinafter also referred to as an arithmetic element PE) provided in the element layer 20 and ACC memories MB1 and MB2 provided to be stacked over the arithmetic element PE are provided. In the element layer 20, a CPU memory MEM in which the OS layers are stacked and a power supply circuit PC are provided.

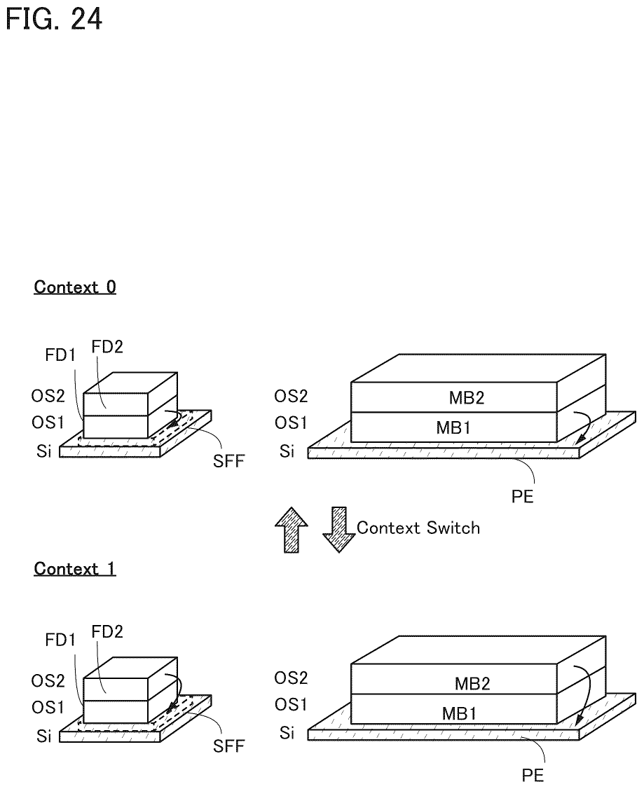

FIG. 24 is a schematic diagram illustrating bank switching of the OS flip-flop (OSFF) and bank switching of the arithmetic element PE. By switching the backup memory FD1 and the backup memory FD2, which are provided on the flip-flop circuit SFF, when data is read from the backup memories FD1 and FD2, the bank switching of the OS flip-flop (OSFF) is performed. By switching the ACC memory MB1 and the ACC memory MB2, which are provided over the arithmetic element PE, when the data is read from the ACC memories MB1 and MB2, the bank switching of the arithmetic element PE is performed. FIG. 24 illustrates that the backup memory FD1 and the ACC memory MB1 are provided in an OS layer OS1, the backup memory FD2 and the ACC memory MB2 are provided in an OS layer OS2, and the scan flip-flop SFF and the arithmetic element PE are provided in the element layer Si including a Si CMOS circuit.

The bank switching can be performed by switching the two states, Context 0 and Context 1 (also referred to as Context Switch). In Context 0, data is read from the backup memory FD1 and the ACC memory MB1 in the OS layer OS1 to the scan flip-flop SFF and the arithmetic element PE. In Context 1, data is read from the backup memory FD2 and the ACC memory MB2 in the OS layer OS2 to the scan flip-flop SFF and the arithmetic element PE.

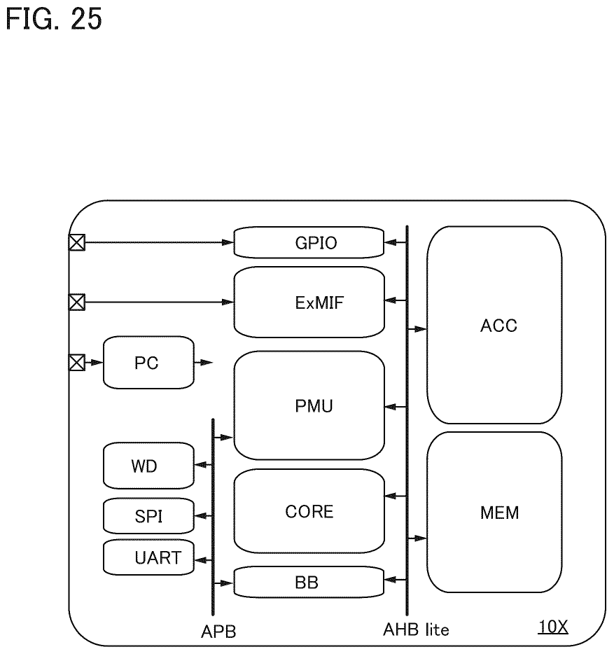

FIG. 25 illustrates a system structure of the fabricated semiconductor device 10X. In the fabricated semiconductor device 10X, an ARM Cortex-M0 CPU (CORE), a 8 Kbyte CPU memory (MEM), an accelerator (ACC), a power supply circuit (PC), a power management circuit (PMU), a General Purpose IO (GPIO), an external memory IF (External Memory Interface, ExMIF), a bus bridge (BB), a Watchdog (WD), and a serial communication interface (SPI and UART) are mounted. The circuits are electrically connected to each other through an AHB bus (AHB lite), an APB bus (APB), or the like.

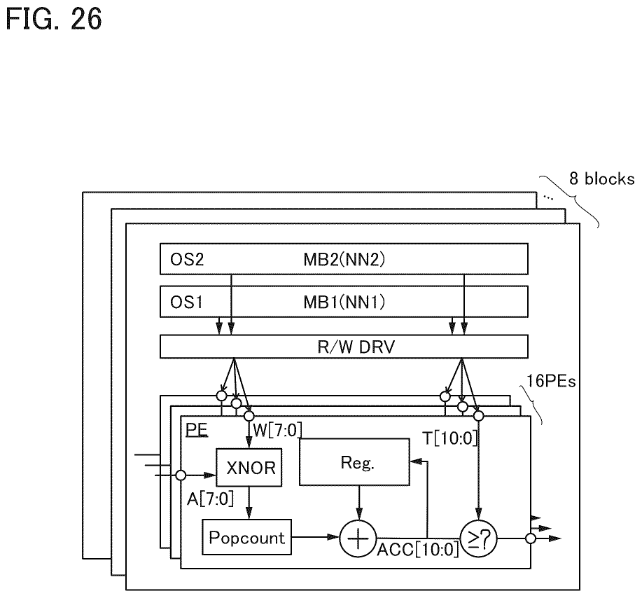

The accelerator (ACC) has a structure of an AI accelerator in which a memory (ACC memory) for weight data of an artificial neural network (NN) is provided over the arithmetic element PE (FIG. 26). The placement of the arithmetic element PE per block is determined; are arranged 8 blocks in each of which two layers of 4 KB memory are shared with 16 arithmetic elements PEs according to a trade-off between the reduction in the driver area due to a large number of memory block divisions and the improvement in the latency due to a small number of memory block divisions. Since the OS layers are stacked so that two NOSRAMs retain different weight data (NN1 and NN2), the arithmetic element PE has a structure in which two states (Context 0 and Context 1) can be switched.

The accelerator (ACC) corresponds to a Binary Neural Network (BNN) for low-power operation. The accelerator includes a controller incorporating a memory/AI mode switching function and a serializer-deserializer (SerDes) in addition to a mechanism for changing the parallel number of the arithmetic elements PE driven in accordance with the neural network. In the arithmetic element PE, weight data (W[7:0]) and input data (A[7:0]) are input to XNOR. The weight data is read from the ACC memories MB1 and MB2 through a driver circuit (R/W DRV). A counter (Popcount) counts XNOR data, and the data is added to data of an accumulator (register Reg.). Eight product-sum operations (MAC) are executed in parallel with one clock and the results are temporarily stored in the accumulator (register Reg.), whereby data (ACC[10:0]) obtained by the product-sum operations can be obtained. After the MAC operations are repeated in accordance with the number of inputs (neurons), threshold processing (bias data T[10:0]) is performed so that arithmetic operations for one layer of the network are completed. The bias data is read from the ACC memories MB1 and MB2 through the driver circuit (R/W DRV). The maximum number of the arithmetic elements PE to be driven in parallel is 128. In the case of a fully connected network with three hidden layers, inference can be performed with 194 clocks.

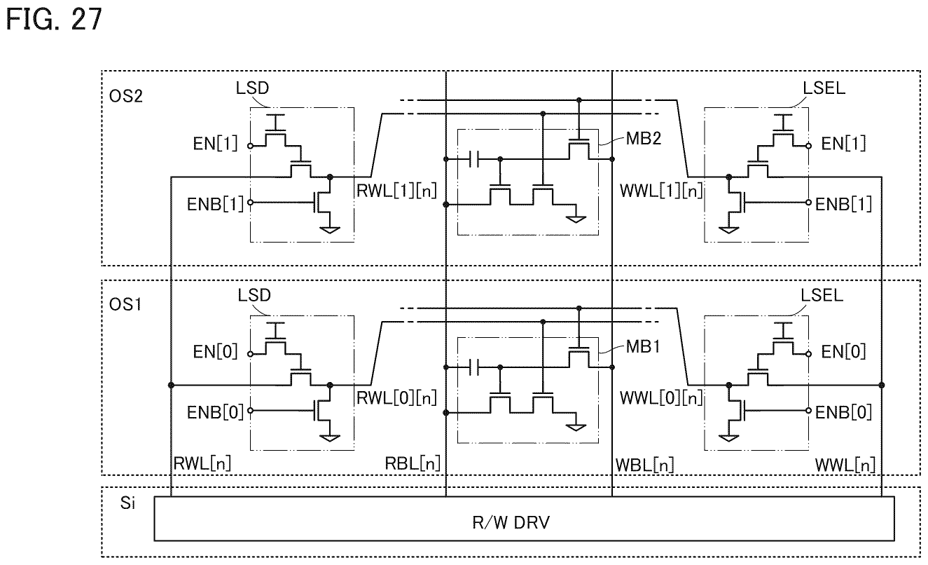

The OS layer including the ACC memory to be accessed can be selected by a layer selection driver LSD fabricated using only an OS transistor (FIG. 27). The layer selection driver LSD includes a bootstrap circuit in order to suppress threshold-voltage drop of word lines (RWL and WWL) generated by switches of an n-channel transistors (nMOS). The layer selection driver LSD and the memory cells of the ACC memories MB1 and MB2 can be provided in the OS layer at the same time; thus, area overhead is not caused even when the number of stacked layers is increased. In addition, the address size of the driver circuit (R/W DRV) fabricated using Si-CMOS does not need to be changed, and its area and power do not increase.

The CPU has a normally-off CPU structure which is capable of power gating. A CPU core of the CPU is Cortex-M0 (registered trademark) produced by ARM, Inc. The backup memory is placed right above the scan flip-flop SFF, and the OS layers are also stacked with zero area overhead. Additionally, a fine-grained random arrangement is possible by utilizing a characteristic of monolithic stacking. Since the OS layers are stacked so that two backup memories can retain different weight data, the two states (Context 0 and Context 1) can be switched.

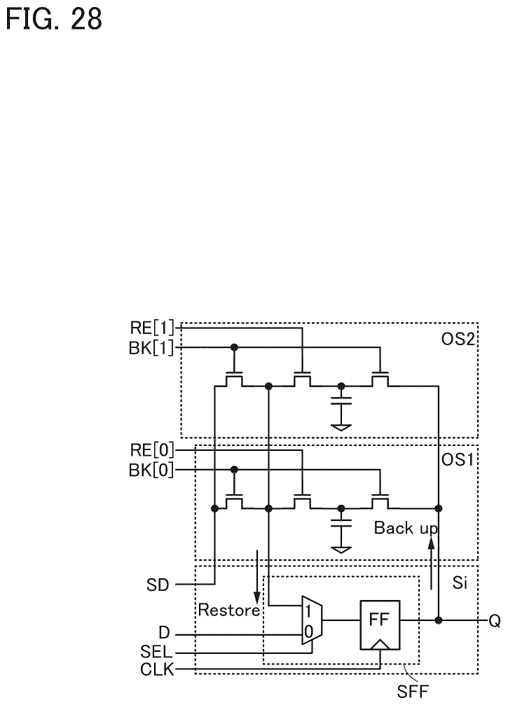

In the OS flip-flop (OSFF), a 3T1C/unit memory is placed right above the scan flip-flop SFF, and the OS layers are stacked with zero area overhead (FIG. 28). The scan flip-flop SFF includes a flip-flop (FF). Additionally, a fine-grained random arrangement is possible by utilizing a characteristic of monolithic stacking. Data backup (Back up) and data restore (Restore) can be performed between the 3T1C/unit memory and the scan flip-flop SFF.

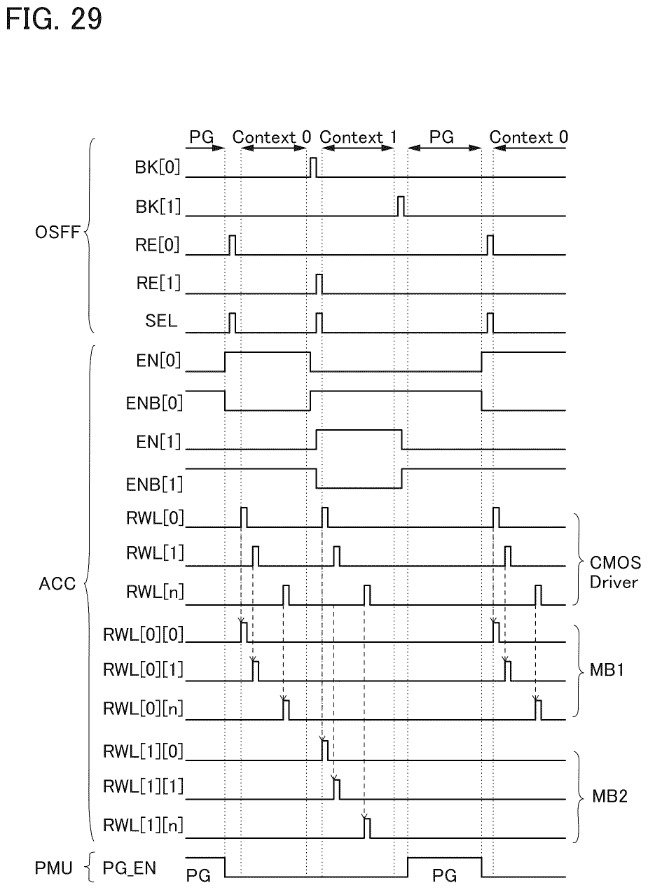

FIG. 29 is a timing chart for describing operation of the accelerator (ACC) shown in FIG. 27 and the OS flip-flop (OSFF) shown in FIG. 28 at the time of switching Context 0 and Context 1. FIG. 29 shows a timing chart for describing operation of a signal (PG_EN) for power gating (PG) by a power management circuit (PMU).

In the OS flip-flop (OSFF), data is saved with the signal BK[0] (BK[1]) corresponding to Context 0 (Context 1) into the memory in the OS layer in the first layer (second layer), and data is written back to the scan flip-flop SFF with the signal RE[1] (RE[0]) corresponding to Context 1 (Context 0). The task and result are backed up by the signal BK[1] (BK[0 ]), whereby context switching is achieved. After data saving, PG is possible in a sleep mode. Backup/restore were performed on 4045 scan flip-flops SFF collectively at 160 ns/ 180 ns, and the energies thereof were 510 fJ/bit/111 fJ/bit according to the chip evaluation.

In the ACC memories MB1 and MB2 included in the accelerator ACC, context switching can be performed only by switching of the layer selection signal. When the read word line (RWL) is activated with the CMOS driver in a state where any of the OS layers is selected, the ACC memory cell MB1 or MB2 in the row of the selected OS layer can be accessed. In the PG, data is retained by the ACC memories MB1 and MB2, and thus a special operation is not required.

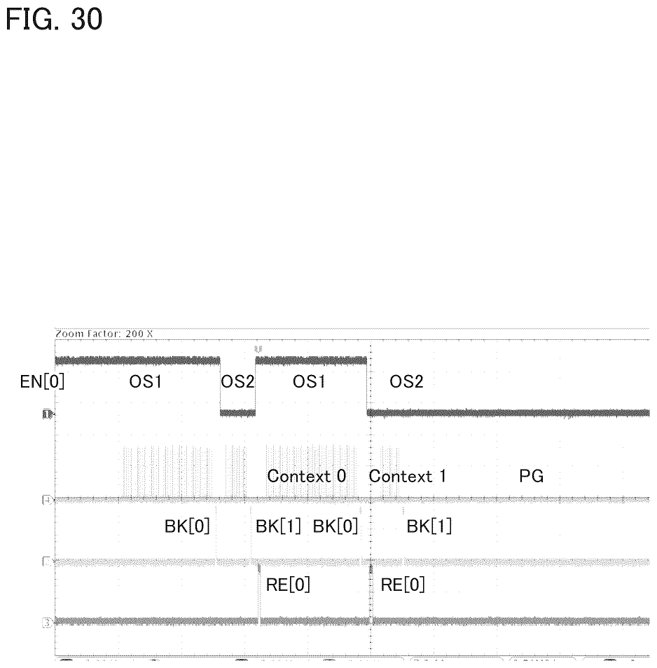

A signal waveform of the fabricated semiconductor device 10X was observed. As shown in FIG. 30, the waveforms in switching the OS1 and the OS2, switching the signal BK[0] and BK[1], and switching the signal RE[0] and RE[1] due to switching of the context were observed.

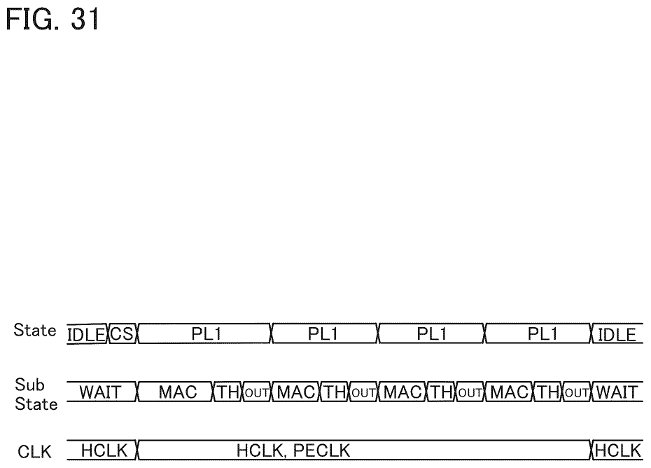

FIG. 31 is a diagram illustrating the state of an arithmetic operation when the arithmetic element PEs are driven in parallel in the accelerator (ACC). In the arithmetic operation, a product-sum operation (MAC), a threshold value processing (TH), and an output (OUT) were performed in each layer (PL1 to PL4). HCLK was set to 10 MHz and PECLK (access clock) was set to 400 kHz. In the case of a fully connected network including 784 input layers (PL1) and three hidden layers (PL2 to PL4: 128 layers), inference can be performed with 194 clocks.

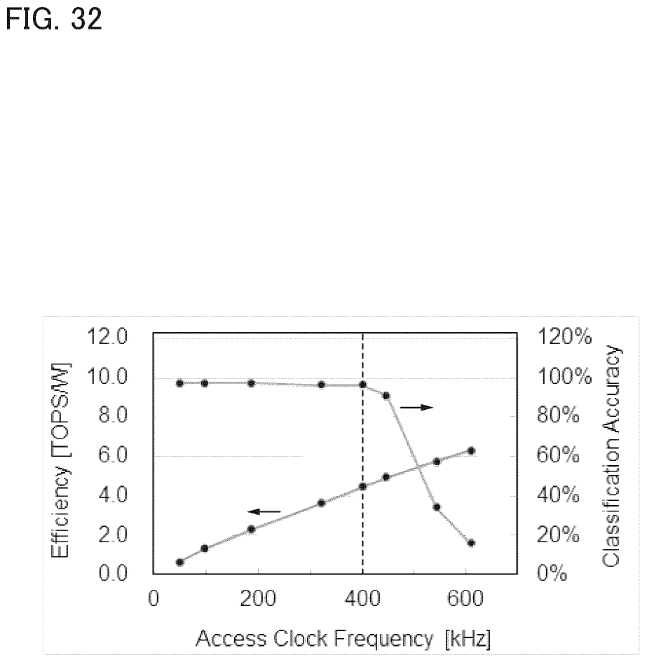

FIG. 32 is a graph showing the results of the chip evaluation, with the left vertical axis representing calculation efficiency, the right vertical axis representing classification accuracy, and the horizontal axis representing access clock frequency. As shown in FIG. 32, the condition of high classification accuracy of the accelerator ACC and high access clock frequency was 4.44 TOPS/W (at a PECLK (access clock frequency) of 400 kHz and a system clock frequency of 10 MHz). Memory reading for inference is a critical path, and the inference accuracy decreases at a maximum frequency (400 kHz); however, there is room for improvement in performance by memory optimization.

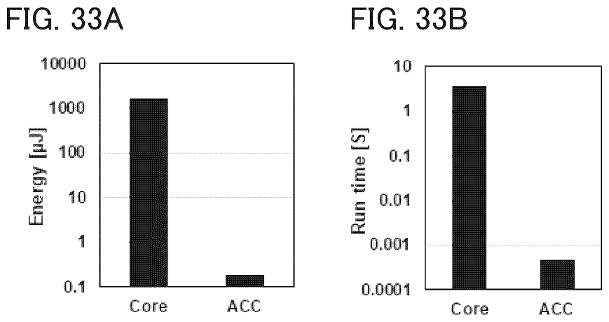

FIG. 33A is a graph showing energy comparison between inference using only the CPU memory and the core (CORE) (using MNIST database) and inference using the accelerator ACC. FIG. 33A is a graph with the vertical axis representing energy (Energy). As compared with an energy of the inference using only the CPU memory and the core (CORE) of 1681.97 μJ, the energy of the inference by the accelerator ACC was reduced to 0.19 μJ. FIG. 33B is a graph with the vertical axis representing running time (Run time). The execution time of the inference was also shortened from 3.55 s to 485 μs (FIG. 33B). As a result, it was confirmed that inference was possible in accordance with the frame rate of imaging data (e.g., 60 fps or 16 ms).

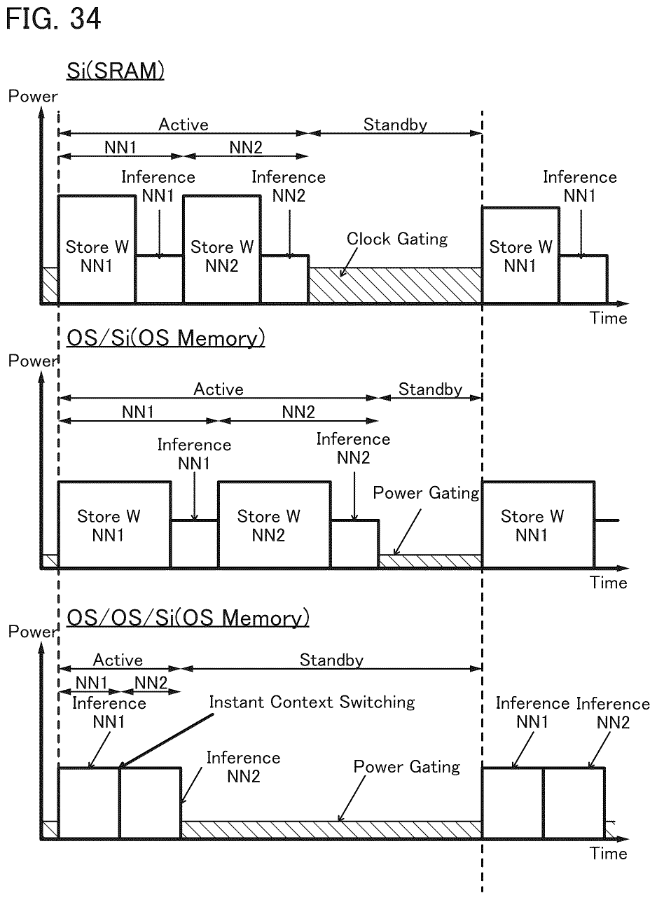

FIG. 34 is a schematic diagram showing the effect of reducing power consumption with performing context switching and power gating (PG), which is compared between a chip with the structure of this example, which includes two OS layers (OS/OS/Si (OS Memory) structure), a chip with the OS/Si (OS Memory) structure including one OS layer, and a chip with the Si (SRAM) structure with no OS layer. FIG. 34 is a graph with the vertical axis representing power (Power) and the horizontal axis representing time (Time). The OS/Si chip is a chip in which only one layer of OS memory is stacked over a CMOS circuit. The Si (SRAM) chip is a chip where an accelerator is not formed with OS but formed with SRAM. The SRAM cannot perform PG because it is a volatile memory; therefore, comparison was performed with a structure in which power in a standby state is reduced by clock gating (CG).

The electric power is estimated using, as an example, intermittent operation in which PG (CG) is performed (Standby period) after the inference (using the MNIST database) is performed (Active period) by switching the two neural networks (NN1 and NN2).

Both the chip with the OS/Si structure and the chip with the accelerator having the Si (SRAM) structure (estimated by a SRAM generator) enable only data of one neural network to be stored in the memory. Thus, rewriting of weight data W is required for every inference. Specifically, with each of the Si (SRAM) structure and the OS/Si (OS Memory) structure, the weight data W of the neural network NN1 is retained (Store W NN1), inference (Inference NN1) is performed, the weight data W of the neural network NN2 is retained (Store W NN2), inference (Inference NN2) is performed, and then the operations are repeated.

On the other hand, with the stacked OS/OS/Si structure, a context switch can be quickly achieved (Instant Context Switching), and power consumption can be reduced by ensuring time for PG. Specifically, with the OS/OS/Si (OS Memory) structure, inference can be performed by switching the weight data W of the neural networks NN1 and NN2; thus, inference (Inference NN1) and inference (Inference NN2) can be successively performed.

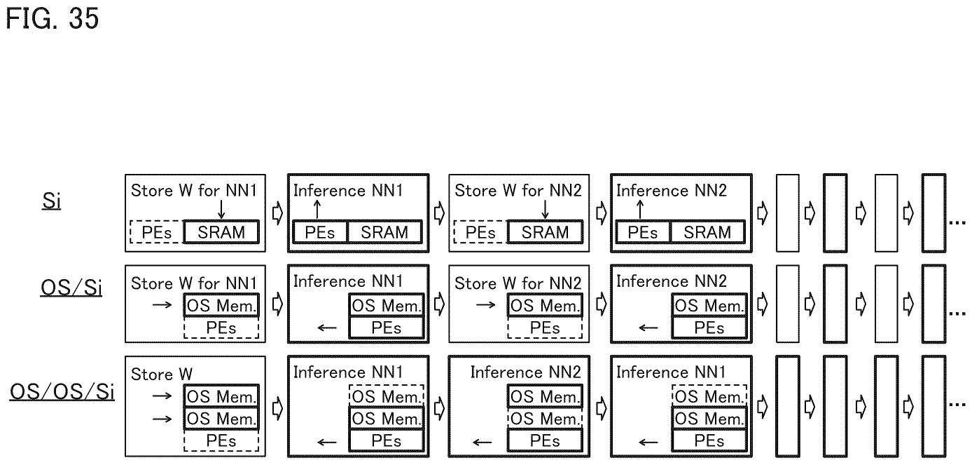

FIG. 35 is a schematic diagram, related to FIG. 34, comparing the operations of the accelerators of the OS/OS/Si structure, the OS/Si structure, and the Si (SRAM) structure in the case where context switching is performed.

As illustrated in FIG. 35, with the Si (SRAM) structure and the OS/Si structure, the weight data W of the neural network NN1 is retained in the SRAM or the OS Mem. (Store W for NN1), inference (Inference NN1) is performed with the arithmetic element PEs, the weight data W of the neural network NN2 is retained in the SRAM or the OS Mem. (Store W for NN2) and inference (Inference NN2) is performed, and then the operations are repeated.

Meanwhile, with the stacked OS/OS/Si structures, it is possible to retain the weight data W of the neural networks NN1 and NN2 in two layers of OS Mem. (Store W) and to perform inference (Inference NN1 and Inference NN2) by switching the data of the OS Mem. Thus, inference (Inference NN1) and inference (Inference NN2) can be successively performed.

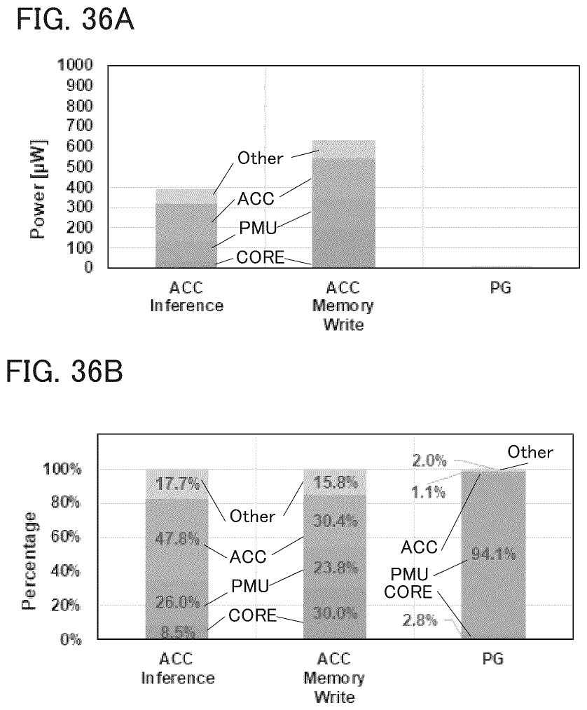

FIG. 36A represents the vertical axis as power (Power), and shows the measurement results of power of the chip with the OS/OS/Si structure including two OS layers at the time of inference using the accelerator ACC (ACC Interference), at the time of the ACC memory writing (ACC Memory Write), and at the time of PG. FIG. 36A also illustrates the details of the power of the CORE, the PMU, the ACC, and the other (Other). FIG. 36B represents the vertical axis as percentage (Percentage), and shows the proportion of the power of the CORE, the PMU, the ACC, and the other (Other) in the chip with the OS/OS/Si structure including two OS layers, at the time of inference using the accelerator ACC, at the time of ACC memory writing, and at the time of PG.

FIG. 36A and FIG. 36B show the results such that the power at the time of the inference using the accelerator ACC, at the time of the ACC memory writing, and at the time of the PG were 386.5 μW, 637.4 μW, and 0.89 μW, respectively. On the assumption of the inference at a frame rate of 60 fps, the average power of the chip is 25.15 μW, which means that the power can be by 79% as compared with the Si (SRAM) structure.

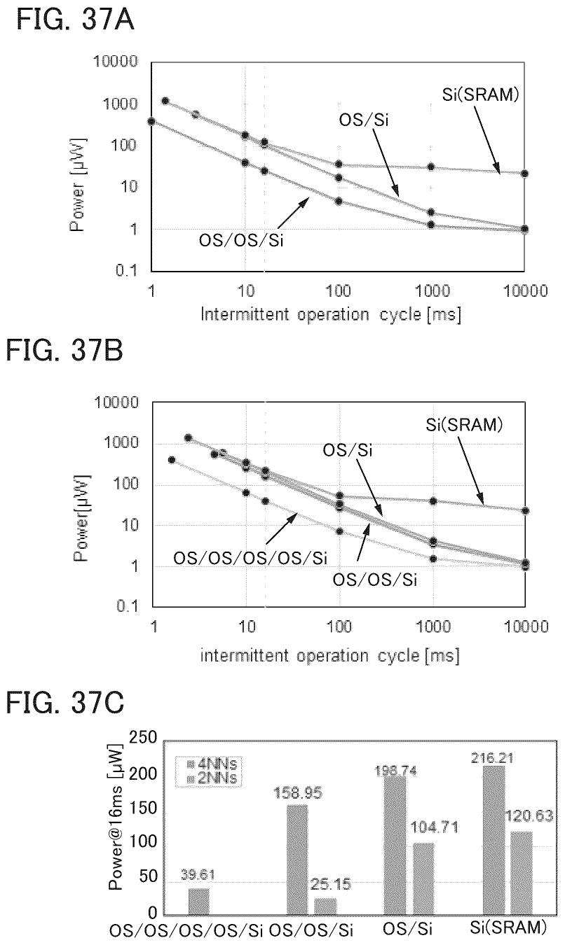

FIG. 37A is a graph showing a relation between power consumption (Power: vertical axis) and frequency (Intermittent operation cycle: horizonal axis) of the accelerators in the OS/OS/Si structure, the OS/Si structure, and the Si (SRAM) structure when operation was performed by switching neural networks with two layers (2NN). It is found that power consumption in the OS/OS/Si structure can be reduced when the operation is performed by switching the two-layer neural networks.

FIG. 37B is a graph showing a relation between power consumption (Power: vertical axis) and frequency (Intermittent operation cycle: horizontal axis) of the accelerators in an OS/OS/OS/OS/Si structure, the OS/OS/Si structure, the OS/Si structure, and the Si (SRAM) structure when operation was performed by switching neural networks with four layers (4NN). When the operation is performed by switching the four-layer neural networks, the effect of reducing power consumption in the OS/OS/Si structure is small. When the number of OS layers is provided in accordance with the number of layers in a neural network, an effect of reducing power consumption can be enhanced.

FIG. 37C is a diagram comparing power consumption of the accelerators at the time of performing switching the neural networks with two layers (2NN) and the neural networks with four layers (4NN) at 16 ms (Power @16 ms: vertical axis) in the OS/OS/OS/OS/Si structure, the OS/OS/Si structure, the OS/Si structure, and the Si (SRAM) structure. As shown in FIG. 37C, when the number of the OS layers is provided in accordance with the number of layers in a neural network, an effect of reducing power consumption can be reduced.

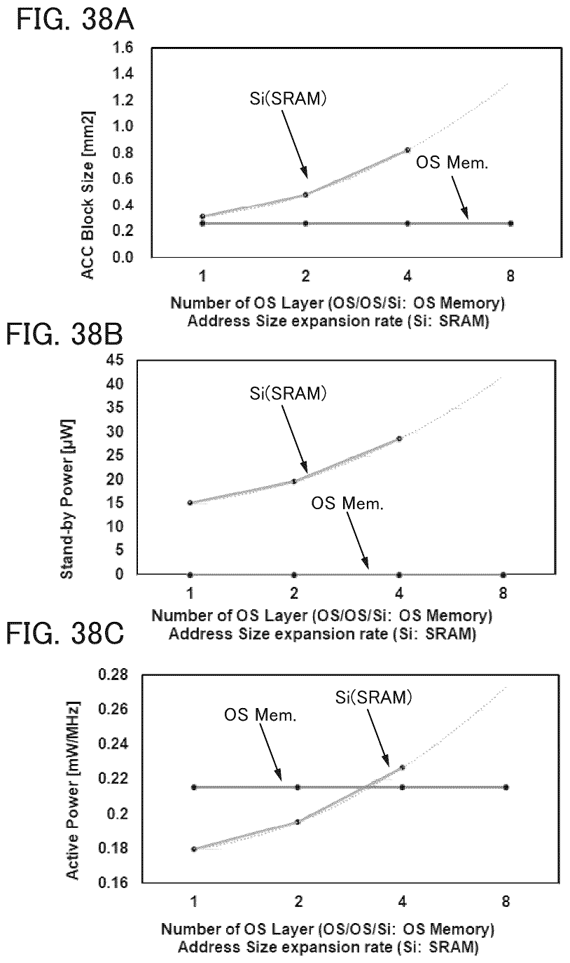

FIG. 38A is a graph showing a relation between a structure in which the number of included OS layers corresponding to the number of neural networks (the number of networks is 1, 2, 4, or 8) (Number of OS Layer (OS/OS/Si: OS Memory)) and the block size (ACC Block Size) of the accelerator. Similarly, FIG. 38B is a graph showing a relation between a structure in which the number of included OS layers corresponding to the number of neural networks (the number of networks is 1, 2, 4, or 8) and a stand-by power (Stand-by Power) at the time of PG. Similarly, FIG. 38C is a graph showing a relation between a structure in which the number of included OS layers corresponding to the number of neural networks (the number of networks is 1, 2, 4, or 8) and driving power consumption (Active Power). Note that in FIG. 38A to FIG. 38C, the block size, the stand-by power, and the power consumption of the accelerator in the case where the number of neural networks is increased in a Si (SRAM) structure without an OS layer (Address Size expansion rate (Si: SRAM)) are also shown.

As illustrated in FIG. 38A to FIG. 38C, in the structure of the accelerator in which the number of OS layers corresponds to the number of neural networks (the number of networks is 1, 2, 4, or 8), the block size is not changed even when the number of the OS layers is increased in accordance with increasing the number of neural networks. The same applies to the stand-by power and the power consumption. In the Si (SRAM) structure, the block size, the power consumption, and the stand-by power are increased in accordance with increasing number of neural networks. When the number of neural networks is small, the Si (SRAM) structure is advantageous in the power consumption.

As described above, rewriting of the ACC memory due to context switching was made unnecessary by performing bank switching with memory included in the OS layer, which brings the extension of the execution time of PG; as a result, the advantages can be obtained in both power and range even in the case where a memory is provided in the OS/OS/Si structure including two OS layers, and the effectiveness of this system can be shown.

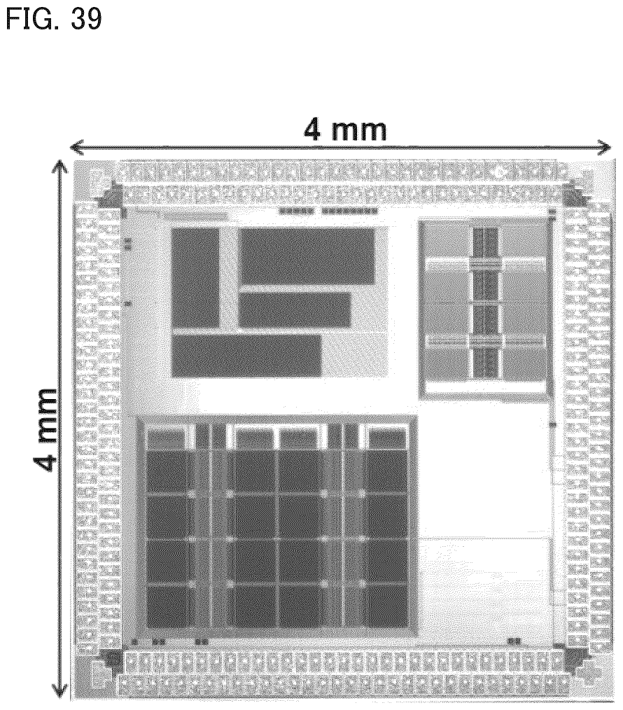

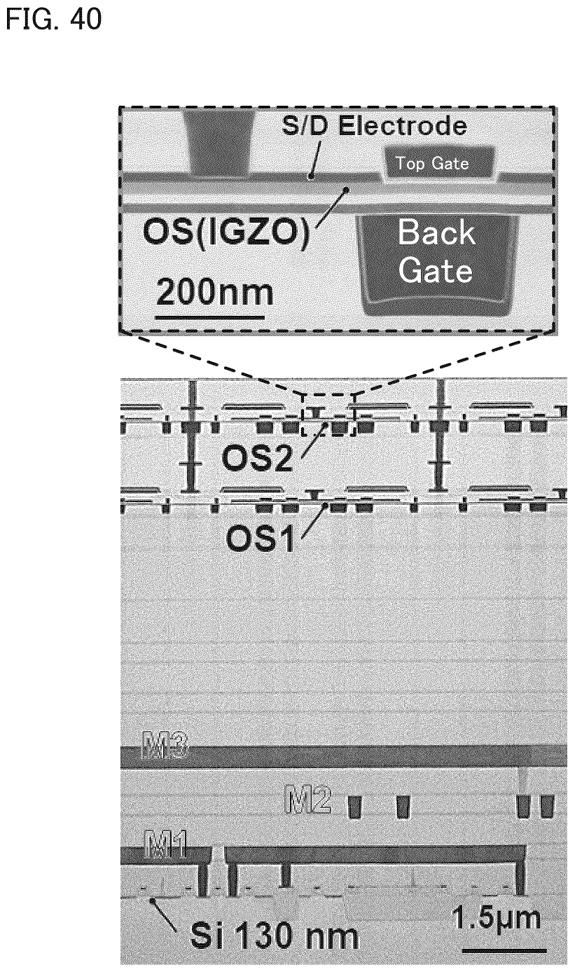

FIG. 39 shows a top-view photograph of a die, and FIG. 40 shows a cross-sectional image of the die. In FIG. 40, S/D Electrode, Top Gate, and Back Gate are shown as a source electrode/ drain electrode, a gate electrode, and a back gate electrode. The semiconductor device described in this example was fabricated through a process in which two element layers of IGZO-FET fabricated with a 200-nm technology were stacked over a Si CMOS circuit fabricated with a 130-nm technology. The OS layers can be used for a backup memory, an ACC memory, and a CPU memory, and can be a structure in which the memory in each layer (OS memory) corresponds to a bank. In the system proposed with this structure, it is possible to extend the stand-by time for performing power gating by associating bank switching of the ACC memory with bank switching of the backup memory and by switching inference of different neural networks with low latency and low power.

### Supplementary Notes on Description in This Specification and the Like

The following are notes on the description of the above embodiments and the structures in the embodiments.

One embodiment of the present invention can be constituted by combining, as appropriate, the structure described in each embodiment with the structures described in the other embodiments. In addition, in the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, a content described in the embodiment is a content described using a variety of diagrams or a content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

Furthermore, in the drawings, the size, the layer thickness, or the region is shown with given magnitude for description convenience. Therefore, the size, the layer thickness, or the region is not limited to the illustrated scale. Note that the drawings are schematically shown for clarity, and embodiments of the present invention are not limited to shapes, values or the like shown in the drawings. For example, variations in a signal, a voltage, or a current due to noise, variations in a signal, a voltage, or a current due to difference in timing, or the like can be included.

In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (or drain) terminal, a source (or drain) electrode, or the like as appropriate depending on the situation.

In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, “voltage” and “potential” can be interchanged with each other as appropriate. The voltage refers to a potential difference from a reference potential, and when the reference potential is ground voltage, for example, the voltage can be rephrased into the potential. The ground potential does not necessarily mean 0 V. Note that potentials are relative values, and a potential applied to a wiring or the like is sometimes changed depending on the reference potential.

In this specification and the like, the terms “film” and “layer” can be interchanged with each other depending on the case or situation. For example, the term “conductive layer” can be replaced with the term “conductive film” in some cases. For another example, the term “insulating film” can be changed into the term “insulating layer” in some cases.

In this specification and the like, a switch has a function of controlling whether current flows or not by being in a conduction state (on state) or a non-conduction state (off state). Alternatively, a switch has a function of selecting and switching a current path.

In this specification and the like, channel length refers to, for example, the distance between a source and a drain in a region where a semiconductor (or a portion where current flows in a semiconductor when a transistor is in an on state) and a gate overlap each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when indicated as an equivalent circuit.

### REFERENCE NUMERALS

10: semiconductor device, 20: element layer, 21: transistor, 22: semiconductor layer, 30: element layer, 31: transistor, 32: semiconductor layer, 100: arithmetic device, 110: register, 120: scan flip-flop, 121: selector, 122: flip-flop, 130: data retention circuit, 132: transistor, 133: transistor, 134: transistor, 135: capacitor, 200: arithmetic device, 210: memory circuit, 211: arithmetic circuit, 220: layer selection circuit, 221: write word line driver portion, 230: layer selection circuit, 231: read word line driver portion, 241: readout circuit, 300: memory device, 310: memory layer

1. A semiconductor device comprising a first arithmetic device comprising a register and a second arithmetic device comprising a plurality of memory circuits, a plurality of layer selection circuits, and an arithmetic circuit,
wherein the first arithmetic device and the second arithmetic device are provided in an element layer in which a plurality of second element layers are stacked over a first element layer, wherein the first element layer comprises a first transistor comprising silicon in a first semiconductor layer comprising a first channel formation region, wherein the second element layer comprises a second transistor comprising an oxide semiconductor in a second semiconductor layer comprising a second channel formation region, wherein the register comprises a flip-flop and a plurality of data retention circuits, wherein the flip-flop and the arithmetic circuit are provided in the first element layer, wherein the data retention circuit is provided in the of second element layer over the flip-flop and
wherein the memory circuit and the layer selection circuit are provided in the second element layer over the arithmetic circuit-provided

2. The semiconductor device according to claim 1,
wherein an input terminal of the flip-flop is electrically connected to each of output terminals of the plurality of data retention circuits, and an output terminal of the flip-flop is electrically connected to each of input terminals of the plurality of data retention circuits, and
wherein the data retention circuits is configured to retain data corresponding to a task executed by the first arithmetic device when the second transistor is turned off.

3. The semiconductor device according to claim 1,
wherein the memory circuit comprises a plurality of memory cells electrically connected to a write word line and a read word line, and
wherein the layer selection circuit is configured to output a signal supplied to the write word line and the read word line.

4. The semiconductor device according to claim 1,
wherein the plurality of memory circuits provided in different second element layers each comprise weight data used for arithmetic processing based on a neural network, and
wherein the weight data input to the arithmetic circuit is switched by the layer selection circuit.

5. The semiconductor device according to claim 1,
wherein the data retention circuit comprises a region overlapping with the flip-flop in a plan view.

6. The semiconductive device according to claim 1,
wherein the memory circuit comprises a region overlapping with the arithmetic circuit in a plan view.

7. The semiconductor device according to claim 1,
wherein the oxide semiconductor comprises In, Ga, and Zn.

8. The semiconductor device according to claim 1,
wherein the arithmetic circuit is configured to perform a product-sum operation.
